(19) United States
(12) Patent Application Publication
(10) Pub. No.: US 2015/0128000 A1
(43) Pub. Date: May 7, 2015

(54) METHOD OF OPERATING MEMORY SYSTEM

(71) Applicant: Samsung Electronics Co., Ltd., Suwon-Si (KR)

(72) Inventors: Ju-Yun JUNG, Hwaseong-si (KR); Min-Yeab CHOO, Suwon-si (KR); Do-Geun KIM, Seoul (KR); Mi-Kyoung PARK, Seoul (KR); Dong-Yang LEE, Yongin-si (KR); Sun-Young LIM, Hwaseong-si (KR); Bu-Il JUNG, Hwaseong-si (KR); Hyuk HAN, Seoul (KR)

(21) Appl. No.: 14/531,250

(22) Filed: Nov. 3, 2014

(30) Foreign Application Priority Data
Nov. 5, 2013 (KR) 10-2013-0133374
Nov. 12, 2013 (KR) 10-2013-0136744

(51) Int. Cl. G11C 29/44; G06F 11/22

(52) U.S. Cl. CPC G11C 29/44; G06F 11/2268
USPC 714/723

(57) ABSTRACT

In a method of operating a memory system including a memory device and a memory controller, the memory controller reads fail information from a fail info region included in the memory device. The memory controller maps a logical address related to a program to a physical address of a safe region based on the fail information to store the program in the safe region except the fail info region and a fail region included in the memory device. The memory controller loads the program into the safe region of the memory device according to the address mapping. The method of operating the memory system according to example embodiments increases the performance of the memory system.

### CROSS-REFERENCE TO RELATED APPLICATION

This application claims priority under 35 USC §119 to Korean Patent Applications No. 10-2013-0133374, filed on Nov. 5, 2013, and No. 10-2013-0136744, filed on Nov. 12, 2013, in the Korean Intellectual Property Office (KIPO), the contents of which are herein incorporated by reference in their entirety.

### BACKGROUND

1. Technical Field

Example embodiments relate generally to a memory system and more particularly to a method of operating a memory system including a memory device and a memory controller.

2. Description of the Related Art

In semiconductor chips, bad cells may develop in a memory cell array of a memory device, for example, while manufacturing the memory device. If data is written in the bad cell corresponding to a fail address or if the data is read from the bad cell, errors may be generated. Therefore it may be desirable to block access to the address of the bad cell included in the memory cell array.

### SUMMARY

Some example embodiments provide a method of operating a memory system capable of enhancing performance of the memory system using fail address information stored in a memory device.

In a method of operating a memory system including a memory device and a memory controller according to example embodiments, the memory controller is initialized, and the memory controller reads a fail information from a fail info region included in the memory device. The memory controller maps a logical address related to a program to a physical address of a safe region based on the fail information to store the program in the safe region except the fail info region and a fail region included in the memory device. The memory controller loads the program into the safe region of the memory device according to the address mapping.

The memory device may include the fail info region and a data region. A data received from the memory controller may be stored in the data region. The fail info region may be a non-volatile memory and the data region may be a volatile memory.

The fail information may be stored in the fail info region based on a test result of the memory device. A test of the memory device may be performed before the memory device is packaged.

The fail info region may include fail information cell units. If a value of the fail information cell unit is a first level, an unit fail information may be bad and if a value of the fail information cell unit is a second level, an unit fail information may be good.

Each of the fail information cell units may include an electrical fuse. The unit fail information may be stored in the fail information cell units included in the fail info region by programming the electrical fuse.

The address mapping may be determined according to the fail information included in fail information cell units of the fail info region.

The program may be a boot loader or an operating system.

The operating system may load an application program into the safe region based on the fail information.

The memory controller may map the logical address related to the program to the physical address of the safe region based on the fail information and an address mapping table to store the program in the safe region.

In a method of operating a memory system including a hybrid memory device and a memory controller according to example embodiments, the memory controller is initialized. The memory controller reads a fail information of a non-volatile memory and a volatile memory from a fail info region of the hybrid memory device, the hybrid memory device including the non-volatile memory and the volatile memory. The memory controller maps a logical address related to a data to a physical address of a safe region based on the fail information to store the data in the safe region, the safe region being divided from the fail info region and a fail region. The memory controller stores the data in the safe region according to the mapping.

The non-volatile memory may include the fail info region and a non-volatile memory safe region. The data received from the memory controller may be stored in the non-volatile memory safe region. The volatile memory may include a volatile memory fail region and a volatile memory safe region. The data received from the memory controller may be stored in the volatile memory safe region. The fail information may be stored in the fail info region.

The fail information stored in the fail info region may be renewed based on a test result of the hybrid memory device. A test of the hybrid memory device may be performed while the memory system is operated.

The memory controller may re-map the logical address to the physical address of the safe region based on the renewed fail information to store the data in the safe region.

The fail information may be stored in the fail info region of the non-volatile memory based on a test result of the hybrid memory device. A test of the hybrid memory device may be performed after the memory system including the non-volatile memory, the volatile memory and the memory controller may be packaged in one chip.

The memory controller may map the logical address to the physical address of the safe region based on an address mapping table to maintain a process order of the data.

At least some example embodiments relates to a method of operating a memory device.

In some example embodiments, the method includes reading, by a memory controller, fail information from the memory device, the memory device including a non-volatile memory storing the fail information therein, the fail information indicating bad sectors of the memory device; mapping logical addresses of a program to physical addresses of the memory device based on the fail information such that the mapping prevents the program from accessing the bad sectors; and loading the program into the mapped physical addresses.

In some example embodiments, the method further includes testing the memory device for the bad sectors at a time of manufacturing a same; and programming the non-volatile memory with the fail information based on the testing.

In some example embodiments, the fail information is stored in corresponding fail information cells included in the non-volatile memory, each of the fail information cells includes an electrical fuse, and the programming the non-volatile memory includes breaking the fuse based on the testing.

In some example embodiments, the method further includes retesting the memory device for the bad sectors at a time of operating the same; and updating the fail information programmed in the non-volatile memory based on the retesting.

In some example embodiments, the reading the fail information from the memory device includes transferring the fail information from the non-volatile memory to an address mapping table in the memory controller, the address mapping table indicating an order to process data.

In some example embodiments, the loading the program loads the program such that the program is not loaded into fail regions of the memory device, the fail regions being regions of the memory device containing the bad sectors.

### BRIEF DESCRIPTION OF THE DRAWINGS

Illustrative, non-limiting example embodiments will be more clearly understood from the following detailed description taken in conjunction with the accompanying drawings.

FIG. 1 is a flow chart illustrating a method of operating a memory system according to example embodiments.

FIG. 2 is a block diagram illustrating the memory system according to an example embodiment.

FIG. 3 is a block diagram illustrating a storing region included in a memory device in FIG. 2.

FIG. 4 is a diagram illustrating an example of a fail information cell unit included in the storing region of FIG. 3.

FIG. 5 is a diagram for describing the method of operating the memory system of FIG. 1.

FIG. 6 is a block diagram illustrating the memory system for describing the method of operating the memory system of FIG. 1.

FIG. 7 is a diagram illustrating an example of loading a program in the storing region of FIG. 3.

FIG. 8 is a diagram illustrating another example of loading a program in the storing region of FIG. 3.

FIG. 9 is a block diagram illustrating a memory system according to example embodiments.

FIG. 10 is a flow chart illustrating a method of operating a memory system according to example embodiments.

FIG. 11 is a block diagram illustrating a memory system according to an example of embodiment.

FIG. 12 is a block diagram illustrating a storing region of a non volatile memory included in the memory system of FIG. 11.

FIG. 13 is a diagram illustrating an example of addresses assigned in a hybrid memory device of FIG. 11.

FIG. 14 is a diagram illustrating an example of a test result of the hybrid memory device.

FIG. 15 is a diagram illustrating another example of the test result of the hybrid memory device.

FIG. 16 is a block diagram illustrating the memory system for describing the method of operating the memory system of FIG. 10.

FIG. 17 is a block diagram illustrating an example of the memory system included in a package substrate.

FIG. 18 is a block diagram illustrating a memory system according to example embodiments.

FIG. 19 is a diagram illustrating an example of mapping logical addresses to physical addresses in the memory system of FIG. 11.

FIG. 20 is a diagram illustrating an example of data stored in a storing region of a volatile memory included in the memory system of FIG. 18.

FIG. 21 is a diagram illustrating an example of programs loaded into the storing region of the volatile memory included in the memory system of FIG. 18.

FIG. 22 is a diagram illustrating an example of the data stored in a storing region of a non-volatile memory included in the memory system of FIG. 18.

FIG. 23 is a diagram illustrating another example of the program loaded in the storing region of the volatile memory included in the memory system of FIG. 18.

FIG. 24 is a diagram illustrating an example of the program loaded in the storing region of the non volatile memory included in the memory system of FIG. 18.

FIG. 25 is a block diagram illustrating a mobile device including the memory system according to example embodiments.

FIG. 26 is a block diagram illustrating a computing system including the memory system according to example embodiments.

### DETAILED DESCRIPTION OF EXAMPLE EMBODIMENTS

Various example embodiments will be described more fully hereinafter with reference to the accompanying drawings, in which some example embodiments are shown. The inventive concepts may, however, be embodied in many different forms and should not be construed as limited to the example embodiments set forth herein. Rather, these example embodiments are provided so that this disclosure will be thorough and complete, and will fully convey the scope of the inventive concepts to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the inventive concepts. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Unless otherwise defined, all terms (including technical and scientific terms) used herein have the same meaning as commonly understood by one of ordinary skill in the art to which these inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

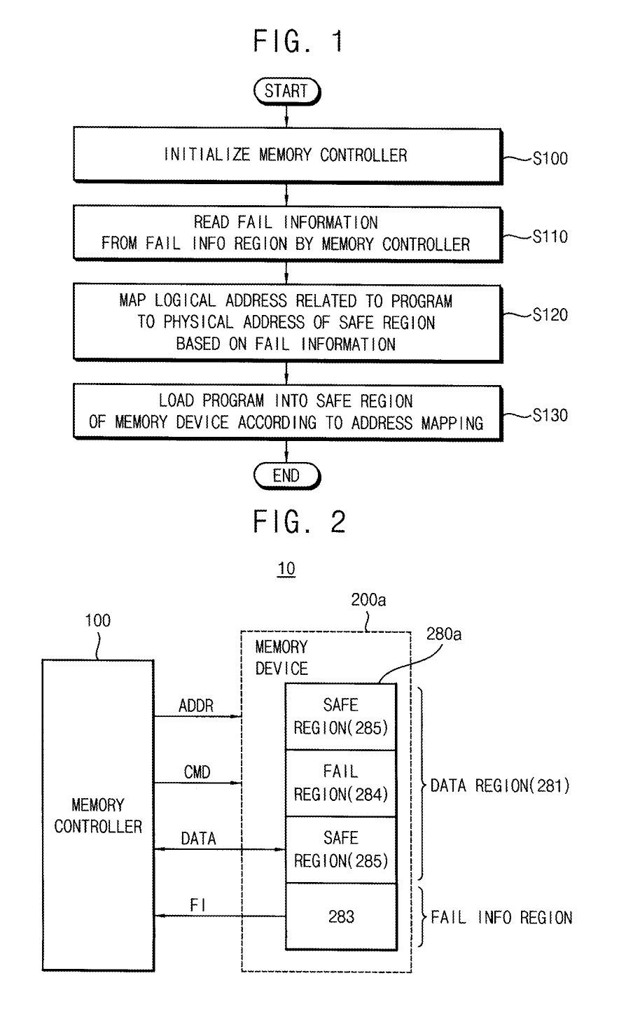

FIG. 1 is a flow chart illustrating a method of operating a memory system according to example embodiments and FIG. 2 is a block diagram illustrating the memory system according to an example embodiment.

Referring to FIGS. 1 and 2, in a method of operating a memory system 10, a memory controller 100 is initialized (S100). The memory system 10 may include a memory device 200a and the memory controller 100. When a whole system including the memory system 10 is booted, the memory controller 100 included in the memory system 10 may be initialized. In other words, a power-up sequence may be performed for the memory system 10.

The memory controller 100 reads a fail information FI from a fail info region 283 included in the memory device 200a (S110). Using commands CMD and addresses ADDR, the memory controller 100 may read the fail information FI from the fail info region 283 included in the memory device 200a. The command CMD may be a read command and the addresses ADDR may be the addresses ADDR corresponding to the fail info region 283 included in the memory device 200a.

The memory device 200a may include a storing region 280a. The storing region 280a may include a data region 281 and the fail info region 283. The data region 281 may include a fail region 284 and a safe region 285.

The fail information FI may be stored in the fail info region 283. The fail information FI may be information about addresses of the fail region 284 included in the data region 281 of the memory device 200a. If the memory controller 100 writes the data in the safe region 285 included in the data region 281, errors may not be generated for the data written in the safe region 285 and if the memory controller 100 reads the data from the safe region 285 included in the data region 281, errors may not be generated for the data read from the safe region 285. If the memory controller 100 writes the data in the fail region 284, errors may be generated for the data written in the fail region 284 and if the memory controller 100 reads the data from the fail region 284, errors may be generated for the data read from the fail region 284.

The memory controller 100 maps a logical address related to a program to a physical address of a safe region 285 based on the fail information FI. Therefore, the memory controller 100 stores the program in the safe region 285, and does not store the program in the fail info region 283 or the fail region 284 included in the memory device 200a (S120). The memory controller 100 may distinguish the fail region 284 and the safe region 285 within the data region 281 according to the fail information FI included in the fail info region 283. The memory controller 100 may map the logical address related to the program to the physical address of the safe region 285 based on the fail information FI.

The memory controller 100 may stop assigning the logical address related to the program to the physical address of the fail region 284 so that the program is not stored in the fail region 284 included in the memory device 200a. The memory controller 100 may assign the logical address related to the program to the physical address of the safe region 285 so that the program is stored in the safe region 285 included in the memory device 200a.

The memory controller 100 loads the program into the safe region 285 of the memory device 200a according to the address mapping (S130).

After the memory controller 100 maps the logical address related to the program to the physical address of the safe region 285 included in the memory device 200a using the fail information FI, the memory controller 100 may load the program into the safe region 285 according to the address mapping.

Thereafter, the memory system 10 may execute the program loaded into the safe region 285 and perform various computing operations therewith.

In the method of operating the memory system 10 according to example of embodiments, the memory controller 100 may load the program into the safe region 285 included in the memory device 200a based on the fail information FI. According to the method of operating the memory system 10, the memory controller 100 may stop accessing the physical address corresponding to the fail region 284 included in the memory device 200a based on the fail information FI and malfunction of the memory system 10 may be prevented. The fail information FI may be transmitted to system level including the memory controller 100 and, using the fail information FI, an operating system may load an application program to the safe region 285 included in the memory device 200a.

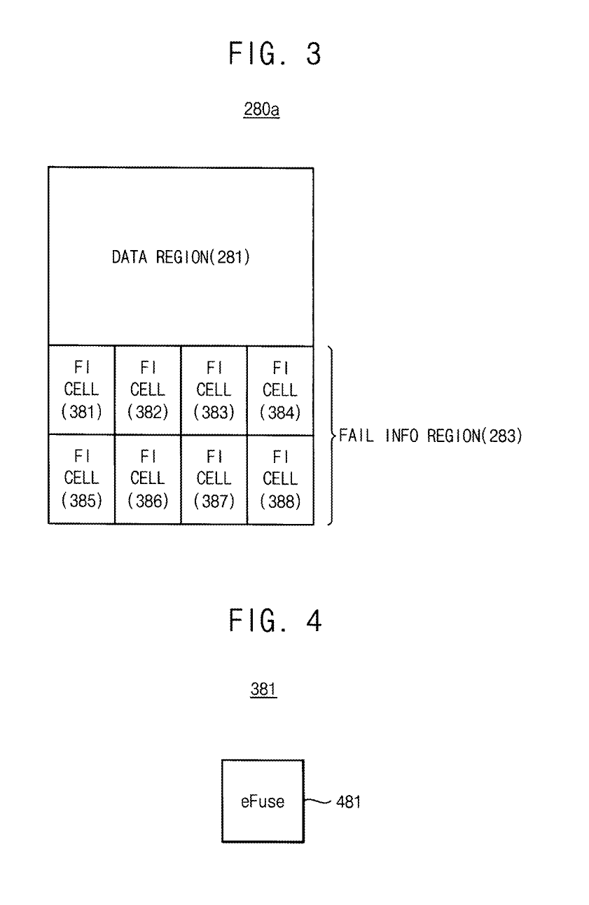

FIG. 3 is a block diagram illustrating a storing region included in a memory device in FIG. 2.

Referring to FIGS. 2 and 3, the memory device 200a may include the storing region 280a. The storing region 280a may include the fail info region 283 and the data region 281.

A data received from the memory controller 100 may be stored in the data region 281. The fail information FI may be stored in the fail info region 283. The fail information FI may contain the addresses of the fail region 284 included in the data region 281 of the memory device 200a.

The fail info region 283 may be a region of a non-volatile memory and the data region 281 may be a region of a volatile memory. If the memory system 10 is booted, the memory controller 100 included in the memory system 10 may be initialized. If the memory controller 100 is initialized, the memory controller 100 reads the fail information FI from the fail info region 283 included in the memory device 200a. The memory controller 100 may read the fail information FI from the fail info region 283 after the memory controller 100 is initialized. In case the fail info region 283 is non-volatile memory, the fail information FI may be maintained even though the power of the memory system 10 shuts down.

The data region 281 may include the fail region 284 and the safe region 285. If the memory controller 100 writes the data in the fail region 284, errors may be generated for the data written in the fail region 284 and if the memory controller 100 reads the data from the fail region 284, errors may be generated for the data read from the fail region 284.

Referring to FIG. 3, the fail information FI may be stored in the fail info region 283 based on a test result of the memory device 200a. A test of the memory device 200a may be performed before the memory device 200a is packaged. The test of the memory device 200a may be a process to test whether cells in the memory device 200a are good cells or bad cells. As the test result of the memory device 200a, when the cell corresponding to the address is a bad cell, a unit fail information UFI may be stored in a fail information cell unit corresponding to the address of the fail information cell units 381 to 388 included in the fail info region 283.

For example, the addresses assigned to the data region 281 may be from 0x000 to 0x111. A first fail information cell unit 381 may store unit fail information UFI corresponding to the address 0x000, a second fail information cell unit 382 may store the unit fail information UFI corresponding to the address 0x001, a third fail information cell unit 383 may store the unit fail information UFI corresponding to the address 0x010, a fourth fail information cell unit 4 384 may store the unit fail information UFI corresponding to the address 0x011, a fifth fail information cell unit 385 may store the unit fail information UFI corresponding to the address 0x100, a sixth fail information cell unit 386 may store the unit fail information UFI corresponding to the address 0x101, a seventh fail information cell unit 387 may store the unit fail information UFI corresponding to the address 0x110 and a eight fail information cell unit 388 may store the unit fail information UFI corresponding to the address 0x111.

While in the example embodiment discussed above, the unit fail information UFI corresponding to the one address assigned to the data region 281 may be stored in the fail information cell unit, example embodiments are not limited thereto. For example, the unit fail information UFI may be generated by grouping a plurality of the addresses assigned to the data region 281. For example, the addresses assigned to the data region 281 may be from 0x0000 to 0x1111. A fail information cell unit 1 381 may store the unit fail information UFI corresponding to the address 0x0000 and 0x0001. In this case, when at least one of the cells corresponding to the address 0x0000 and 0x0001 is a bad cell, the unit fail information UFI may be bad.

In the method of operating the memory system 10 according to example of embodiments, the memory controller 100 may load the program into the safe region 285 included in the memory device 200a based on the fail information FI. According to the method of operating the memory system 10, the memory controller 100 may stop accessing the physical address corresponding to the fail region 284 included in the memory device 200a based on the fail information FI and malfunction of the memory system 10 may be prevented. The fail information FI may be transmitted to system level including the memory controller 100 and, using the fail information FI, an operating system may load an application program to the safe region 285 included in the memory device 200a.

In some example embodiments, the fail info region 283 may include fail information cell units 381 to 388. If a portion of the memory device corresponding to the unit fail information UFI is bad, a value of the fail information cell unit may be a first level. Likewise, if a portion of the memory device corresponding to the unit fail information UFI is good, a value of the fail information cell unit may be a second level different from the first level. In other words, a first level of the unit fail information indicates that a corresponding portion of the memory device is bad and a second level of the unit fail information indicates that the corresponding portion of the memory device is good. The first level may be a logic high level and the second level may be a logic low level. In another example embodiment, the first level may be the logic low level and the second level may be the logic high level.

The unit fail information UFI may be generated by grouping a plurality of the addresses assigned to the data region 281. For example, the addresses assigned to the data region 281 may be from 0x0000 to 0x1111. The first fail information cell unit 381 may store the fail information FI of the cells corresponding to the address 0x0000 and 0x0001 as the unit fail information UFI. In this case, when at least one of the cells corresponding to the address 0x0000 and 0x0001 is a bad cell, the unit fail information UFI may be bad.

The second fail information cell unit 382 may store the fail information FI of the cells corresponding to the address 0x0010 and 0x0011 as the unit fail information UFI. The third fail information cell unit 383 may store the fail information FI of the cells corresponding to the address 0x0100 and 0x0101 as the unit fail information UFI. The fourth fail information cell unit 384 may store the fail information FI of the cells corresponding to the address 0x0110 and 0x0111 as the unit fail information UFI. The fifth fail information cell unit 385 may store the fail information FI of the cells corresponding to the address 0x1000 and 0x1001 as the unit fail information UFI. The sixth fail information cell unit 386 may store the fail information FI of the cells corresponding to the address 0x1010 and 0x1011 as the unit fail information UFI. The seventh fail information cell unit 387 may store the fail information FI of the cells corresponding to the address 0x1100 and 0x1101 as the unit fail information UFI. The eighth fail information cell unit 388 may store the fail information FI of the cells corresponding to the address 0x1110 and 0x1111 as the unit fail information UFI.

In some example embodiments, if the value of the fail information cell unit is 1, the unit fail information UFI may be bad and if the value of the fail information cell unit is 0, the unit fail information UFI may be good. In another example embodiment, if the value of the fail information cell unit is 0, the unit fail information UFI may be bad and if the value of the fail information cell unit is 1, the unit fail information UFI may be good.

If the unit fail information UFI stored in the fail information cell unit is bad, the address in the data region 281 corresponding to the unit fail information UFI may be included in the fail region 284. If the memory controller 100 writes the data in the fail region 284, errors may be generated for the data written in the fail region 284 and if the memory controller 100 reads the data from the fail region 284, errors may be generated for the data read from the fail region 284.

FIG. 4 is a diagram illustrating an example of a fail information cell unit included in the storing region of FIG. 3.

Referring to FIGS. 3 and 4, each of the fail information cell units 381 to 388 may include an electrical fuse 481. The unit fail information UFI may be stored in the fail information cell units 381 to 388 included in the fail info region 283 by programming the electrical fuse 481. The fail information cell unit may be implemented using the electrical fuse 481. The electrical fuse 481 included in the fail information cell unit may be programmed by applying a high voltage to a fuse and cutting the fuse. The unit fail information UFI included in the fail information cell unit may be determined based on whether the fuse is cut or not.

In some example embodiments, if the electrical fuse 481 included in the fail information cell unit is cut, the value of the fail information cell unit may be 1 and the unit fail information UFI may be bad. If the electrical fuse 481 included in the fail information cell unit is not cut, the value of the fail information cell unit may be 0 and the unit fail information UFI may be good. In another example embodiment, if the electrical fuse 481 included in the fail information cell unit is cut, the value of the fail information cell unit may be 0 and the unit fail information UFI may be bad. If the electrical fuse 481 included in the fail information cell unit is not cut, the value of the fail information cell unit may be 1 and the unit fail information UFI may be good.

In some example embodiments, if the electrical fuse 481 included in the fail information cell unit is cut, the value of the fail information cell unit may be 1 and the unit fail information UFI may be good. If the electrical fuse 481 included in the fail information cell unit is not cut, the value of the fail information cell unit may be 0 and the unit fail information UFI may be bad. In some example embodiments, if the electrical fuse 481 included in the fail information cell unit is cut, the value of the fail information cell unit may be 0 and the unit fail information UFI may be good. If the electrical fuse 481 included in the fail information cell unit is not cut, the value of the fail information cell unit may be 1 and the unit fail information UFI may be bad.

The fail info region 283 may include the fail information cell units 381 to 388. The unit fail information UFI may be stored in the fail information cell unit included in the fail info region 283. The fail information FI may be stored in the fail info region 283. The fail information FI may contain information about the addresses of the fail region 284 included in the data region 281 of the memory device 200a. Based on the test result of the memory device 200a, when the cell corresponding to the address is a bad cell, the unit fail information UFI may be stored using the electrical fuse 481 included in the fail information cell unit corresponding to the address of the fail information cell units 381 to 388.

For example, the addresses assigned to the data region 281 may be from 0x000 to 0x111. A first electrical fuse 481 included in the first fail information cell unit 381 may store the unit fail information UFI corresponding to the address 0x000, a second electrical fuse (not shown) included in the second fail information cell unit 382 may store the unit fail information UFI corresponding to the address 0x001, a third electrical fuse (not shown) included in the third fail information cell unit 383 may store the unit fail information UFI corresponding to the address 0x010, a fourth electrical fuse (not shown) included in the fourth fail information cell unit 384 may store the unit fail information UFI corresponding to the address 0x011, a fifth electrical fuse (not shown) included in the fifth fail information cell unit 385 may store the unit fail information UFI corresponding to the address 0x100, a sixth electrical fuse (not shown) included in the sixth fail information cell unit 386 may store the unit fail information UFI corresponding to the address 0x101, a seventh electrical fuse (not shown) included in the seventh fail information cell unit 387 may store the unit fail information UFI corresponding to the address 0x110 and an eighth electrical fuse (not shown) included in the eighth fail information cell unit 388 may store the unit fail information UFI corresponding to the address 0x111.

In the method of operating the memory system 10 according to example of embodiments, the memory controller 100 may load the program into the safe region 285 included in the memory device 200a based on the fail information FI. According to the method of operating the memory system 10, the memory controller 100 may stop accessing the physical address corresponding to the fail region 284 included in the memory device 200a based on the fail information FI and malfunction of the memory system 10 may be prevented. The fail information FI may be transmitted to system level including the memory controller 100 and, using the fail information FI, an operating system may load an application program to the safe region 285 included in the memory device 200a.

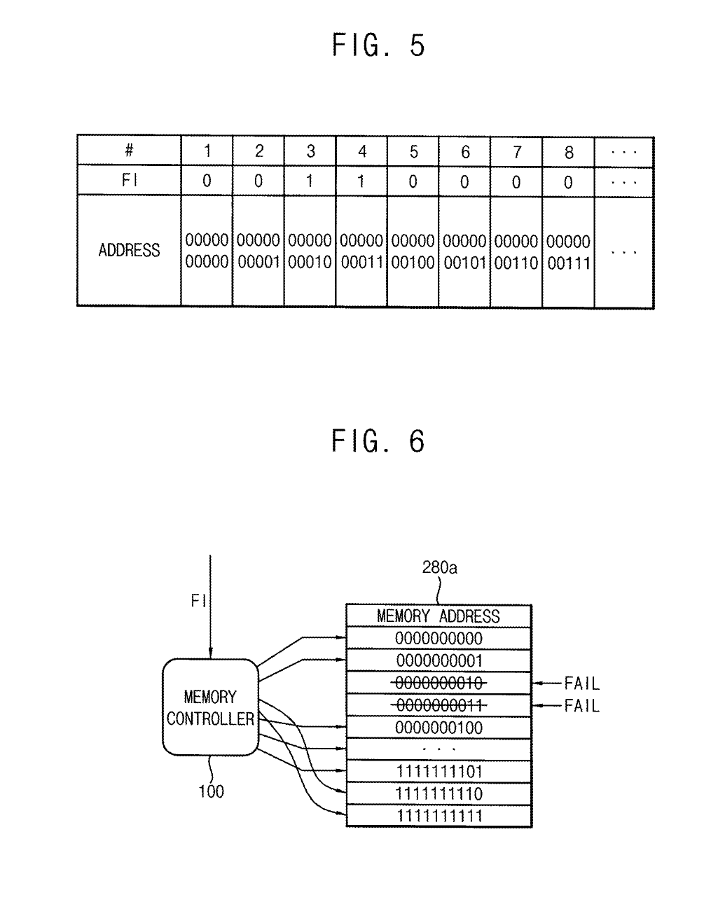

FIG. 5 is a diagram for describing the method of operating the memory system of FIG. 1 and FIG. 6 is a block diagram illustrating the memory system for describing the method of operating the memory system of FIG. 1.

Referring to FIGS. 5 and 6, address mapping may be determined according to the fail information FI included in the fail information cell units 381 to 388 of the fail info region 283. Using the fail information FI, the memory controller 100 may stop loading the data or the program into the fail region 284 included in the memory device 200a.

For example, as illustrated in FIG. 5, the addresses in the memory device 200a may be from 0x0000000000 to 0x1111111111. The value of the fail information cell unit corresponding to the address 0x0000000000 may be 0. The value of the fail information cell unit corresponding to the address 0x0000000001 may be 0. The value of the fail information cell unit corresponding to the address 0x0000000010 may be 1. The value of the fail information cell unit corresponding to the address 0x0000000011 may be 1. The value of the fail information cell unit corresponding to the address 0x0000000100 may be 0. The value of the fail information cell unit corresponding to the address 0x0000000101 may be 0. The value of the fail information cell unit corresponding to the address 0x0000000110 may be 0. The value of the fail information cell unit corresponding to the address 0x0000000111 may be 0.

If the value of the fail information cell unit is 1, the unit fail information UFI may be bad. If the value of the fail information cell unit is 0, the unit fail information UFI may be good. Therefore the cells included in the memory device 200a corresponding to the addresses 0x0000000010 and 0x0000000011 may be bad cells. A region included in the memory device 200a corresponding to the addresses 0x0000000010 and 0x0000000011 may be included in the fail region 284.

The cells included in the memory device 200a corresponding to the addresses 0x0000000000, 0x0000000001, 0x0000000100, 0x0000000101, 0x0000000110 and 0x0000000111 may be the good cells. A region included in the memory device 200a corresponding to the addresses 0x0000000000, 0x0000000001, 0x0000000100, 0x0000000101, 0x0000000110 and 0x0000000111 may be included in the safe region 285.

The fail information FI may be stored in the fail info region 283. The fail information FI may be information about addresses of the fail region 284 included in the data region 281 of the memory device 200a. If the memory controller 100 writes the data in the safe region 285 included in the data region 281, errors may not be generated for the data written in the safe region 285 and if the memory controller 100 reads the data from the safe region 285 included in the data region 281, errors may not be generated for the data read from the safe region 285. If the memory controller 100 writes the data in the fail region 284, errors may be generated for the data written in the fail region 284 and if the memory controller 100 reads the data from the fail region 284, errors may be generated for the data read from the fail region 284. The memory controller 100 may stop accessing the physical address corresponding to the fail region 284 included in the memory device 200a based on the fail information FI.

For example, because the cells included in the memory device 200a corresponding to the addresses 0x0000000010 and 0x0000000011 are the bad cells, the memory controller 100 may stop accessing the physical addresses 0x0000000010 and 0x0000000011. Because the cells included in the memory device 200a corresponding to the addresses 0x0000000000, 0x0000000001, 0x0000000100, 0x0000000101, 0x0000000110 and 0x0000000111 are the good cells, the memory controller 100 may access the physical addresses 0x0000000000, 0x0000000001, 0x0000000100, 0x0000000101, 0x0000000110 and 0x0000000111. The memory controller 100 may stop accessing the physical address corresponding to the fail region 284 included in the memory device 200a. The memory controller 100 may access the physical address corresponding to the safe region 285 included in the memory device 200a.

In this case, the memory controller 100 may read a fail information FI from a fail info region 283 included in the memory device 200a. The fail information FI may be stored in the fail info region 283. The fail information FI may be information about addresses of the fail region 284 included in the data region 281 of the memory device 200a. Using commands CMD and addresses ADDR, the memory controller 100 may read the fail information FI from the fail info region 283 included in the memory device 200a. The command CMD may be a read command and the addresses ADDR may be the addresses corresponding to the fail info region 283 included in the memory device 200a.

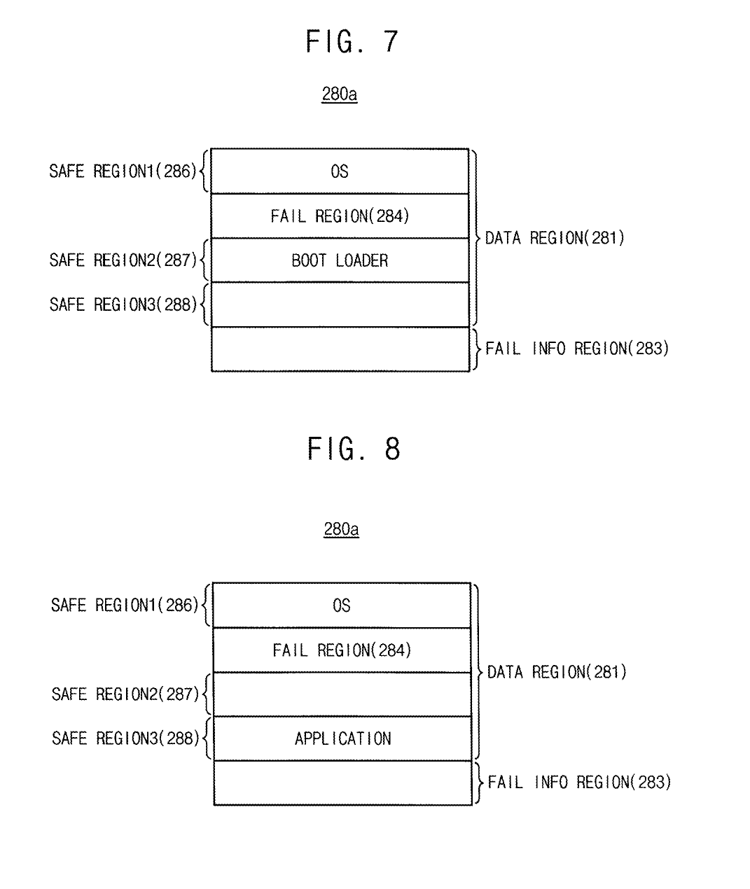

FIG. 7 is a diagram illustrating an example of loading a program in the storing region of FIG. 3.

Referring to FIG. 7, the storing region 280a may include the data region 281 and the fail info region 283. A data received from the memory controller 100 may be stored in the data region 281. The fail information FI may be stored in the fail info region 283. The fail information FI may be the information about the addresses of the fail region 284 included in the data region 281 of the memory device 200a. The program may be a boot loader or an operating system.

The memory controller 100 may map the logical address to a physical address based on the fail information FI to store the boot loader or the operating system in the safe region 285 and not in the fail info region 283 and a fail region 284 included in the memory device 200a. The memory controller 100 may stop mapping the logical address related to the boot loader or the operating system to the physical address of the fail region 284 based on the fail information FI not to store the boot loader or the operating system in the fail region 284 included in the memory device 200a. The memory controller 100 may map the logical address related to the boot loader or the operating system to the physical address of the safe region 285 based on the fail information FI to store the boot loader or the operating system in the safe region 285 included in the memory device 200a. After the memory controller 100 is initialized, the boot loader may initialize devices related to the memory system 10 and the operating system may be loaded in the memory device 200a.

The data region 281 may include the fail region 284 and the safe region 285. The safe region 285 may include a safe region 1 286, a safe region 2 287 and a safe region 3 288. The memory controller 100 may load the boot loader and the operating system to the safe region 285 included in the memory device 200a based on the fail information FI. For example, if the boot loader is loaded to the safe region 1 286, the operating system may be loaded to the safe region 2 287 and the safe region 3 288. If the boot loader is loaded to the safe region 2 287, the operating system may be loaded to the safe region 1 286 and the safe region 3 288. If the boot loader is loaded to the safe region 3 288, the operating system may be loaded to the safe region 1 286 and the safe region 2 287. If the memory controller 100 loads the boot loader and the operating system to the fail region 284 included in the memory device 200a, the program may be incorrectly performed.

FIG. 8 is a diagram illustrating another example of loading a program in the storing region of FIG. 3.

Referring to FIG. 8, the storing region 280a may include the fail info region 283 and the data region 281. The data region 281 may include the fail region 284 and the safe region 285.

The operating system may load an application program into the safe region 285 based on the fail information FI. The fail information FI may be stored in the fail info region 283. The fail information FI may be information about addresses of the fail region 284 included in the data region 281 of the memory device 200a. After the memory controller 100 is initialized, the memory controller 100 may load the operating system to the safe region 285 included in the memory device 200a based on the fail information FI. The operating system may load the application program to the safe region 285 included in the memory device 200a using the fail information FI.

The fail information FI included in the fail info region 283 may be transferred to the memory controller 100. After the operating system is loaded to the safe region 285 included in the memory device 200a, the operating system may load the application program to the safe region 285 using the fail information FI. The fail information FI may be transferred from the fail info region 283 to the operating system through the memory controller 100.

The safe region 285 may include the safe region 1 286, the safe region 2 287 and the safe region 3 288. The operating system may load the application program to the safe region 285 included in the memory device 200a based on the fail information FI. For example, if the operating system is loaded to the safe region 1 286, the application program may be loaded to the safe region 2 287 and the safe region 3 288. If the operating system is loaded to the safe region 2 287, the application program may be loaded to the safe region 1 286 and the safe region 3 288. If the operating system is loaded to the safe region 3 288, the application program may be loaded to the safe region 1 286 and the safe region 2 286.

The fail information FI may be stored in the fail info region 283. The fail information FI may be information about addresses of the fail region 284 included in the data region 281 of the memory device 200a.

In the method of operating the memory system 10 according to example of embodiments, the memory controller 100 may load the program into the safe region 285 included in the memory device 200a based on the fail information FI. According to the method of operating the memory system 10, the memory controller 100 may stop accessing the physical address corresponding to the fail region 284 included in the memory device 200a based on the fail information FI and malfunction of the memory system 10 may be prevented. The fail information FI may be transmitted to system level including the memory controller 100 and, using the fail information FI, an operating system may load an application program to the safe region 285 included in the memory device 200a.

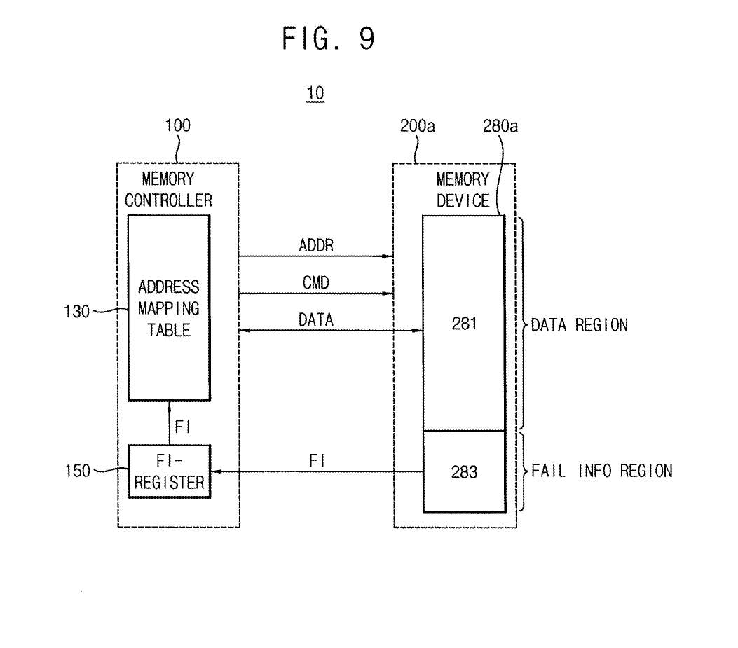

FIG. 9 is a block diagram illustrating a memory system according to example embodiments.

Referring to FIGS. 8 and 9, the memory system 10 may include the memory controller 100 and the memory device 200a. The memory controller 100 may include an address mapping table 130 and a fail information register 150. The memory device 200a may include the storing region 280a. The storing region 280a may include the data region 281 and the fail info region 283.

The memory controller 100 may further include a processor and a memory (not shown).

The processor may be configured to carry out instructions of a computer program by performing the arithmetical, logical, and input/output operations. The processor may read the instructions from the memory via a bus and/or a network interface (not shown). The processor may be a logic chip, for example, a central processing unit (CPU), a controller, or an application-specific integrated circuit (ASIC), that when, executing the instructions stored in the memory, configures the processor as a special purpose machine. More specifically, the instructions may configure the processor to perform the methods illustrated in FIG. 1 and/or 10.

The memory may be a non-transitory computer readable storage medium. The memory may include a random access memory (RAM), read only memory (ROM), and/or a permanent mass storage device, such as a disk drive.

The memory controller 100 may map the logical address related to the program to the physical address of the safe region 285 based on the fail information FI and an address mapping table 130 to store the program in the safe region 285. The memory controller 100 reads the fail information FI from the fail info region 283 included in the memory device 200a. Using commands CMD and addresses ADDR, the memory controller 100 may read the fail information FI from the fail info region 283 included in the memory device 200a. The command CMD may be a read command and the addresses ADDR may be the addresses corresponding to the fail info region 283 included in the memory device 200a.

As illustrated in FIG. 9, the storing region 280a includes the data region 281 and the fail info region 233. If the unit fail information UFI corresponding to the one address assigned in the data region 281 is stored in the fail information cell unit included in the fail info region 283, the space of the storing region 280a allocated to the data region 281 may be decreased. Therefore the address mapping table 130 may be generated by composing a mapping unit for a plurality of the addresses included in the memory device 200a. If the address mapping table 130 is used, the space of the data region 281 included in the memory device 200a may not be decreased.

For example, the addresses assigned to the data region 281 of FIG. 3 may be from 0x000 to 0x111. The first fail information cell unit 381 may store the unit fail information UFI corresponding to the address 0x000, the second fail information cell unit 382 may store the unit fail information UFI corresponding to the address 0x001, the third fail information cell unit 383 may store the unit fail information UFI corresponding to the address 0x010, the fourth fail information cell unit 384 may store the unit fail information UFI corresponding to the address 0x011, the fifth fail information cell unit 385 may store the unit fail information UFI corresponding to the address 0x100, the sixth fail information cell unit 386 may store the unit fail information UFI corresponding to the address 0x101, the seventh fail information cell unit 387 may store the unit fail information UFI corresponding to the address 0x110 and the eighth fail information cell unit 388 may store the unit fail information UFI corresponding to the address 0x111. In this case, the fail information cell units assigned to 8 addresses of the data region 281 may be 8 fail information cell units. As a result, the space of the data region 281 included in the memory device 200a may be decreased.

However, the first fail information cell unit 381 may store the fail information FI of the cells corresponding to the address 0x000 and 0x001 as the unit fail information UFI. The second fail information cell unit 382 may store the fail information FI of the cells corresponding to the address 0x010 and 0x011 as the unit fail information UFI. The third fail information cell unit 383 may store the fail information FI of the cells corresponding to the address 0x100 and 0x101 as the unit fail information UFI. The fourth fail information cell unit 384 may store the fail information FI of the cells corresponding to the address 0x110 and 0x111 as the unit fail information UFI. In this case, the fail information cell units assigned to 8 addresses of the data region 281 may be 4 fail information cell units. As a result, the space of the data region 281 included in the memory device 200a may be increased.

The fail information FI read from the fail info region 283 may be stored in the fail information register 150 included in the memory controller 100. The memory controller 100 may load the program into the safe region 285 included in the memory device 200a according to the address mapping table 130 and the fail information FI stored in the fail information register 150.

The memory controller 100 may stop mapping the logical address related to the program to the physical address of the fail region 284 based on the fail information FI not to store the program in the fail region 284 included in the memory device 200a. The memory controller 100 may map the logical address related to the program to the physical address of the safe region 285 based on the fail information FI to store the program in the safe region 285 included in the memory device 200a.

The address mapping table 130 may be generated by grouping a plurality of row addresses included in the memory device 200a. For example, a number of bits assigned to the row address included in the memory device 200a may be 13 bits. A number of bits assigned to a column address included in the memory device 200a may be 10 bits. A number of bits assigned to a bank address included in the memory device 200a may be 2 bits. A number of bits assigned to a bank group address included in the memory device 200a may be 1 bit. The address mapping table 130 may be generated by composing a mapping unit for 8 of the row addresses. In this case, the total number of the mapping units may be 2̂10*2̂2*2=8000. Because one fail information cell unit may be needed for each of the mapping units, the total number of the fail information cell units may also be 8000.

The address mapping may be determined according to the address mapping table 130 and the fail information FI included in the fail information cell units 381 to 388 of the fail info region 283. Using the fail information FI, the memory controller 100 may stop loading the program and the data into the fail region 284 included in the memory device 200a.

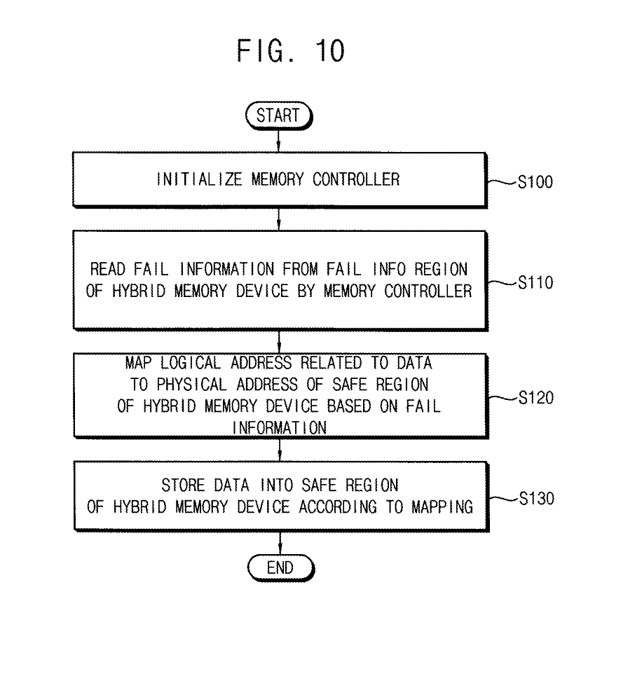

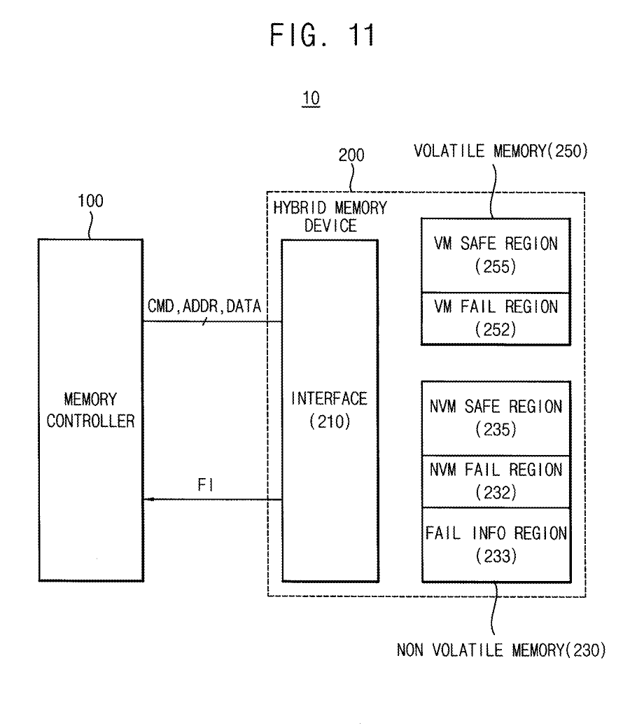

FIG. 10 is a flow chart illustrating a method of operating a memory system according to example embodiments and FIG. 11 is a block diagram illustrating a memory system according to an example of embodiment.

Referring to FIGS. 10 and 11, in a method of operating a memory system 10 including a hybrid memory device 200 and a memory controller 100, the memory controller 100 is initialized S100.

The memory system 10 may include the hybrid memory device 200 and the memory controller 100. If the memory system 10 is booted, the memory controller 100 included in the memory system 10 may be initialized. In other words, a power-up sequence may be performed for the memory system 10.

The memory controller 100 reads a fail information FI of a non-volatile memory 230 and a volatile memory 250 from a fail info region 233 of the hybrid memory device 200. The hybrid memory device 200 may include the non-volatile memory 230 and the volatile memory 250. Using commands CMD and addresses ADDR, the memory controller 100 may read the fail information FI from the fail info region 233 included in the hybrid memory device 200. The command CMD may be a read command and the addresses ADDR may be the addresses corresponding to the fail info region 233 included in the hybrid memory device 200.

The hybrid memory device 200 may include an interface 210, the non-volatile memory 230 and the volatile memory 250 storing data. The interface 210 may provide commands CMD, addresses ADDR and data to the non-volatile memory 230 and the volatile memory 250. The commands CMD, the addresses ADDR and the data may be transferred from the memory controller 100. The non-volatile memory 230 may include a non-volatile memory safe region 235, a non-volatile memory fail region 232 and the fail info region 233. The volatile memory 250 may include a volatile memory safe region 255 and a volatile memory fail region 252.

In some example embodiments, addresses included in the non-volatile memory safe region 235 may be physically successive addresses. In another example embodiment, the addresses included in the non-volatile memory safe region 235 may not be physically successive addresses. Likewise, in some example embodiments, the addresses included in the volatile memory safe region 255 may be physically successive addresses and, in another example embodiment, the addresses included in the volatile memory safe region 255 may not be physically successive addresses.

The fail information FI may be stored in the fail info region 233. The fail information FI may be information about addresses of the fail region included in the non-volatile memory 230 and the volatile memory 250 of the hybrid memory device 200.

If the memory controller 100 writes the data in the safe region included in the hybrid memory device 200, errors may not be generated for the data written in the safe region and if the memory controller 100 reads the data from the safe region included in the hybrid memory device 200, errors may not be generated for the data read from the safe region. The safe region may include the non-volatile memory safe region 235 and the volatile memory safe region 255. If the memory controller 100 writes the data in the fail region, errors may be generated for the data written in the fail region and if the memory controller 100 reads the data from the fail region, errors may be generated for the data read from the fail region. The fail region may include the non-volatile memory fail region 232 and the volatile memory fail region 252.

The memory controller 100 maps a logical address related to a data to a physical address of a safe region based on the fail information FI to store the data in the safe region. The safe region may be divided from the fail info region 233 and a fail region (S120).

The memory controller 100 may distinguish the fail region and the safe region from a storing region a according to the fail information FI included in the fail info region 233. The memory controller 100 may map the logical address related to the data to the physical address of the safe region based on the fail information FI. The data may be written in one or more of the safe regions according to the size of the data.

The memory controller 100 may stop assigning the logical address related to the data to the physical address of the fail region so that the data is not stored in the fail region included in the non-volatile memory 230 and the volatile memory 250. The memory controller 100 may assign the logical address related to the data to the physical address of the safe region so that the data is stored in the safe region included in the non-volatile memory 230 and the volatile memory 250.

The memory controller 100 stores the data in the safe region according to the mapping (S130). After the memory controller 100 maps the logical address related to the data to the physical address of the safe region included in the non-volatile memory 230 and the volatile memory 250 using the fail information FI, the memory controller 100 may load the data to the safe region according to the mapping.

In an example embodiment, the non-volatile memory 230 may include the fail info region 233 and a non-volatile memory safe region 235. The data received from the memory controller 100 may be stored in the non-volatile memory safe region 235. The volatile memory 250 may include a volatile memory fail region 252 and a volatile memory safe region 255. The data received from the memory controller 100 may be stored in the volatile memory safe region 255. The fail information FI may be stored in the fail info region 233.

The non-volatile memory 230 may include the fail info region 233. If the memory system 10 is booted, the memory controller 100 included in the memory system 10 may be initialized. If the memory controller 100 is initialized, the memory controller 100 reads the fail information FI from the fail info region 233 included in the hybrid memory device 200. Because the fail info region 233 is in the non-volatile memory 230, the fail information FI may be maintained in fail info region 233 included in the hybrid memory device 200 even though the power of the memory system 10 shuts down. The non-volatile memory 230 and the volatile memory 250 may include the fail region and the safe region. If the memory controller 100 writes the data in the fail region, errors may be generated for the data written in the fail region and if the memory controller 100 reads the data from the fail region, errors may be generated for the data read from the fail region.

In the method of operating the memory system 10 according to example of embodiments, the memory controller 100 may store the data to the safe region included in the non-volatile memory 230 and the volatile memory 250 based on the fail information FI included in the fail info region 233. According to the method of operating the memory system 10, the memory controller 100 may stop accessing the physical address corresponding to the fail region included in the non-volatile memory 230 and the volatile memory 250 based on the fail information FI and malfunction of the memory system 10 may be prevented. The fail information FI may be transmitted to system level including the memory controller 100 and, using the fail information FI, an operating system may load an application program to the safe region included in the non-volatile memory 230 and the volatile memory 250.

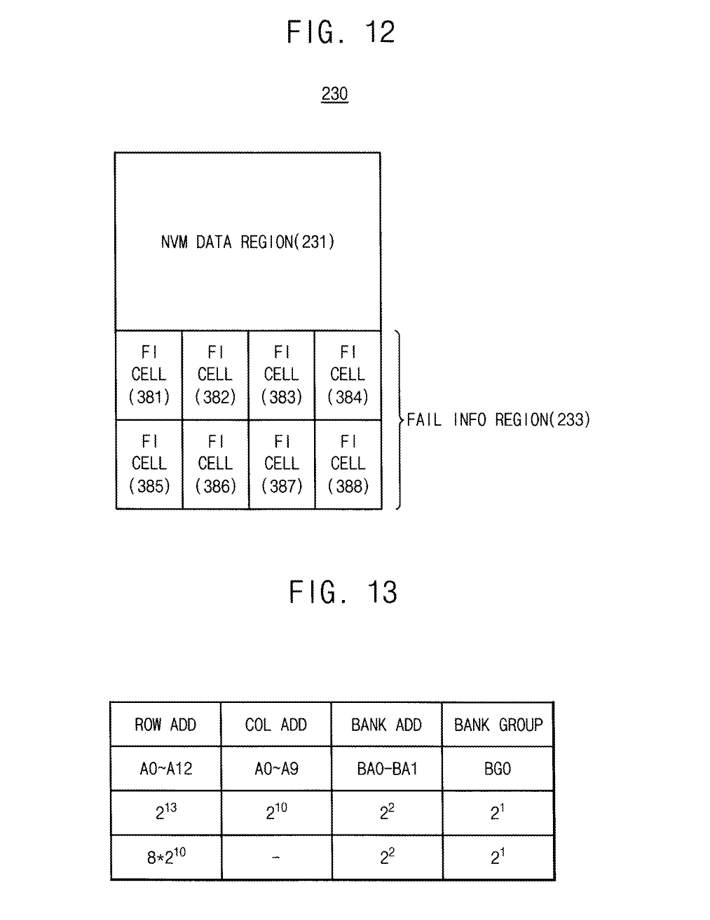

FIG. 12 is a block diagram illustrating a storing region of a non volatile memory included in the memory system of FIG. 11.

Referring to FIG. 12, the non-volatile memory 230 may include a non-volatile memory data region 231 and the fail info region 233. The non-volatile memory data region 231 may include the non-volatile memory safe region 235 and the non-volatile memory fail region 232. The fail information FI may be stored in the fail info region 233. The fail information FI may be information about addresses of the fail region included in the non-volatile memory 230 and the volatile memory 250 of the hybrid memory device 200. The data transferred from the memory controller 100 may be stored in the non-volatile memory data region 231.

The fail information FI may be stored in the fail info region 233 based on a test result of the hybrid memory device 200. A test of the hybrid memory device 200 may be performed before the hybrid memory device 200 is packaged. The test of the hybrid memory device 200 may be a process to test whether cells in the hybrid memory device 200 are good cells or bad cells. As the test result of the memory device, when the cell corresponding to the address is a bad cell, unit fail information UFI may be stored in a fail information cell unit corresponding to the address of the fail information cell units 381 to 388 included in the fail info region 233.

In some example embodiments, the addresses assigned to the storing region of the volatile memory 250 may be from 0x000 to 0x111. The first fail information cell unit 381 may store the unit fail information UFI corresponding to the volatile memory address 0x000, the second fail information cell unit 382 may store the unit fail information UFI corresponding to the volatile memory address 0x001, the third fail information cell unit 383 may store the unit fail information UFI corresponding to the volatile memory address 0x010, the fourth fail information cell unit 384 may store the unit fail information UFI corresponding to the volatile memory address 0x011, the fifth fail information cell unit 385 may store the unit fail information UFI corresponding to the volatile memory address 0x100, the sixth fail information cell unit 386 may store the unit fail information UFI corresponding to the volatile memory address 0x101, the seventh fail information cell unit 387 may store the unit fail information UFI corresponding to the volatile memory address 0x110 and the eighth fail information cell unit 388 may store the unit fail information UFI corresponding to the volatile memory address 0x111.

In another example embodiment, the addresses assigned to the storing region of the non-volatile memory 230 may be from 0x000 to 0x111. The first fail information cell unit 381 may store the unit fail information UFI corresponding to the non-volatile memory address 0x000, the second fail information cell unit 382 may store the unit fail information UFI corresponding to the non-volatile memory address 0x001, the third fail information cell unit 383 may store the unit fail information UFI corresponding to the non-volatile memory address 0x010, the fourth fail information cell unit 384 may store the unit fail information UFI corresponding to the non-volatile memory address 0x011, the fifth fail information cell unit 385 may store the unit fail information UFI corresponding to the non-volatile memory address 0x100, the sixth fail information cell unit 386 may store the unit fail information UFI corresponding to the non-volatile memory address 0x101, the seventh fail information cell unit 387 may store the unit fail information UFI corresponding to the non-volatile memory address 0x110 and the eighth fail information cell unit 388 may store the unit fail information UFI corresponding to the non-volatile memory address 0x111.

In the method of operating the memory system 10 according to example of embodiments, the memory controller 100 may store the data to the safe region included in the non-volatile memory 230 and the volatile memory 250 based on the fail information FI included in the fail info region 233. According to the method of operating the memory system 10, the memory controller 100 may stop accessing the physical address corresponding to the fail region included in the non-volatile memory 230 and the volatile memory 250 based on the fail information FI and malfunction of the memory system 10 may be prevented. The fail information FI may be transmitted to system level including the memory controller 100 and, using the fail information FI, an operating system may load an application program to the safe region included in the non-volatile memory 230 and the volatile memory 250.

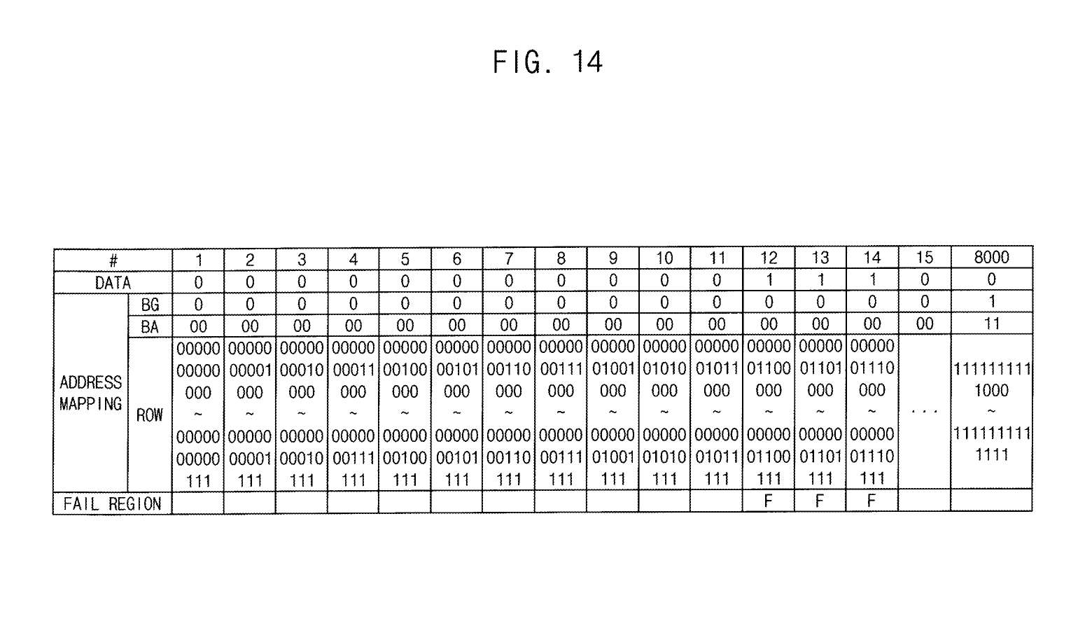

FIG. 13 is a diagram illustrating an example of addresses assigned in a hybrid memory device of FIG. 11 and FIG. 14 is a diagram illustrating an example of a test result of the hybrid memory device.

Referring to FIGS. 12, 13 and 14, the unit fail information UFI corresponding to the one address included in the non-volatile memory 230 and the volatile memory 250 may be stored in the fail information cell unit. However, the unit fail information UFI may be generated by grouping a plurality of the addresses included in the non-volatile memory 230 and the volatile memory 250. The address mapping may be generated by grouping a plurality of row addresses included in the hybrid memory device 200.

For example, a number of bits assigned to the row address (ROW) included in the hybrid memory device 200 may be 13 bits. A number of bits assigned to the column address included in the memory device may be 10 bits. A number of bits assigned to the bank address (BA) included in the memory device may be 2 bits. A number of bits assigned to the bank group address (BG) included in the memory device may be 1 bit. The address mapping may be generated by composing a mapping unit for 8 row addresses. In this case, total number of the mapping units may be 2̂10*2̂2*2=8000. Because one fail information cell unit may be used for each of the mapping units, the total number of the fail information cell units may be 8000.

Using the fail information, the memory controller 100 may stop storing the data to the fail region included in the hybrid memory device 200.

For example, the row addresses in the hybrid memory device 200 may be from 0x0000000000000 to 0x1111111111111. The value (DATA) of the fail information cell unit corresponding to the address 0x0000001100000˜0x0000001100111 may be 1. The value (DATA) of the fail information cell unit corresponding to the address 0x0000001101000˜0x0000001101111 may be 1. The value (DATA) of the fail information cell unit corresponding to the address 0x0000001110000˜0x0000001110111 may be 1.

If the value of the fail information cell unit is 1, the unit fail information UFI may be bad and if the value of the fail information cell unit is 0, the unit fail information UFI may be good. Therefore the cells included in the hybrid memory device 200 corresponding to the row addresses 0x0000001100000˜0x0000001100111, 0x0000001101000˜0x0000001101111 and 0x0000001110000˜0x0000001110111 may be the bad cells. A region included in the hybrid memory device 200 corresponding to the row addresses 0x0000001100000˜0x0000001100111, 0x0000001101000˜0x0000001101111 and 0x0000001110000˜0x0000001110111 may be included in the fail region. Also, the cells included in the hybrid memory device 200 corresponding to the row addresses except for the row addresses 0x0000001100000˜0x0000001100111, 0x0000001101000˜0x0000001101111 and 0x0000001110000˜0x0000001110111 may be the good cells. A region included in the hybrid memory device 200 corresponding to the row addresses except for the row addresses 0x0000001100000˜0x0000001100111, 0x0000001101000˜0x0000001101111 and 0x0000001110000˜0x0000001110111 may be included in the safe region.

If the memory controller 100 writes the data in the safe region included in the hybrid memory device 200, errors may not be generated for the data written in the safe region and if the memory controller 100 reads the data from the safe region included in the hybrid memory device 200, errors may not be generated for the data read from the safe region. If the memory controller 100 writes the data in the fail region, errors may be generated for the data written in the fail region and if the memory controller 100 reads the data from the fail region, errors may be generated for the data read from the fail region. The memory controller 100 may stop accessing the physical address corresponding to the fail region included in the hybrid memory device 200 based on the fail information.

For example, because the cells included in the hybrid memory device 200 corresponding to the row addresses 0x0000001100000˜0x0000001100111, 0x0000001101000˜0x0000001101111 and 0x0000001110000˜0x0000001110111 are the bad cells, the memory controller 100 may stop accessing the physical addresses 0x0000001100000˜0x0000001100111, 0x0000001101000˜0x0000001101111 and 0x0000001110000˜0x0000001110111. Because the cells included in the memory device corresponding to the row addresses except for the row addresses 0x0000001100000˜0x0000001100111, 0x0000001101000˜0x0000001101111 and 0x0000001110000˜0x0000001110111 are the good cells, the memory controller 100 may access the physical addresses except for the row addresses 0x0000001100000˜0x0000001100111, 0x0000001101000˜0x0000001101111 and 0x0000001110000˜0x0000001110111. The memory controller 100 may stop accessing the physical address corresponding to the fail region included in the hybrid memory device 200. The memory controller 100 may access the physical address corresponding to the safe region included in the hybrid memory device 200.

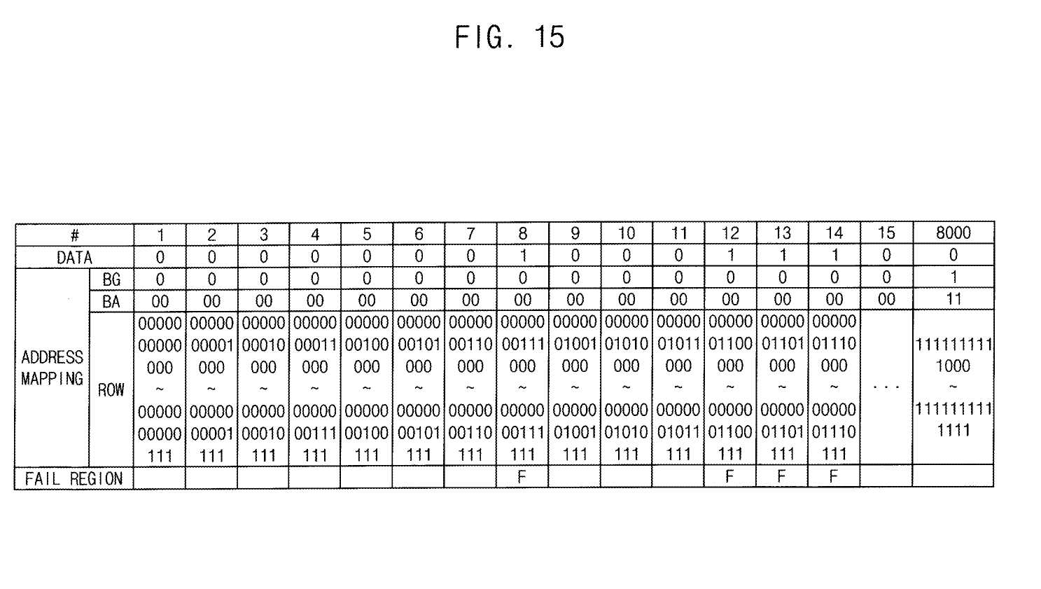

FIG. 15 is a diagram illustrating another example of the test result of the hybrid memory device.

Referring to FIG. 15, the fail information stored in the fail info region 233 may be renewed based on a test result of the hybrid memory device 200. A test of the hybrid memory device 200 may be performed while the memory system 10 is operated. The test of the hybrid memory device 200 performed during the operation of the memory system 10 may be a process to test whether cells in the memory device are good cells or bad cells. As the test result of the hybrid memory device 200, when the cell corresponding to the address is a bad cell, a unit fail information UFI may be renewed in a fail information cell unit corresponding to the address of the fail information cell units 381 to 388 included in the fail info region 233.

For example, using the renewed fail information FI, the memory controller 100 may stop storing the data in the fail region included in the hybrid memory device 200.

The row addresses (ROW) in the hybrid memory device 200 may be from 0x0000000000000 to 0x1111111111111. The value of the fail information cell unit corresponding to the row address 0x0000000111000˜0x0000000111111 may be 1. The value of the fail information cell unit corresponding to the row address 0x0000001100000˜0x0000001100111 may be 1. The value of the fail information cell unit corresponding to the row address 0x0000001101000˜0x0000001101111 may be 1. The value of the fail information cell unit corresponding to the row address 0x0000001110000˜0x0000001110111 may be 1.

In this case, when the test result of the hybrid memory device 200 performed during the operation of the memory system 10 compares to the test result of the hybrid memory device 200 performed before the packaging, the value of the fail information cell unit corresponding to the row address 0x0000000111000˜0x0000000111111 may be renewed from 0 to 1.

The cells included in the hybrid memory device 200 corresponding to the row addresses 0x0000000111000˜0x0000000111111, 0x0000001100000˜0x0000001100111, 0x0000001101000˜0x0000001101111 and 0x0000001110000˜0x0000001110111 may be the bad cells. A region included in the hybrid memory device 200 corresponding to the row addresses 0x0000000111000˜0x0000000111111, 0x0000001100000˜0x0000001100111, 0x0000001101000˜0x0000001101111 and 0x0000001110000˜0x0000001110111 may be included in the fail region. Also, the cells included in the hybrid memory device 200 corresponding to the row addresses except for the row addresses 0x0000000111000˜0x0000000111111, 0x0000001100000˜0x0000001100111, 0x0000001101000˜0x0000001101111 and 0x0000001110000˜0x0000001110111 may be the good cells. A region included in the hybrid memory device 200 corresponding to the row addresses except for the row addresses 0x0000000111000˜0x0000000111111, 0x0000001100000˜0x0000001100111, 0x0000001101000˜0x0000001101111 and 0x0000001110000˜0x0000001110111 may be included in the safe region.

The example of the volatile memory 250 may be applied to the non-volatile memory 230.

In the method of operating the memory system 10 according to example of embodiments, the memory controller 100 may store the data to the safe region included in the non-volatile memory 230 and the volatile memory 250 based on the fail information FI included in the fail info region 233. According to the method of operating the memory system 10, the memory controller 100 may stop accessing the physical address corresponding to the fail region included in the non-volatile memory 230 and the volatile memory 250 based on the fail information FI and malfunction of the memory system 10 may be prevented. The fail information FI may be transmitted to system level including the memory controller 100 and, using the fail information FI, an operating system may load an application program to the safe region included in the non-volatile memory 230 and the volatile memory 250.

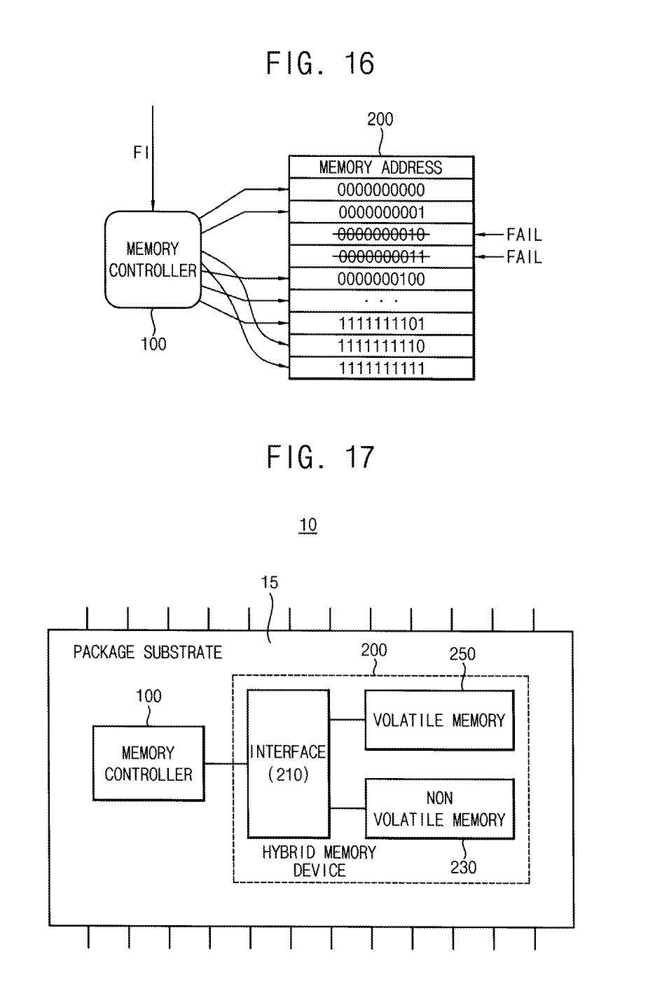

FIG. 16 is a block diagram illustrating the memory system for describing the method of operating the memory system of FIG. 10.

Referring to FIG. 16, the memory controller 100 may re-map the logical address to the physical address of the safe region based on the renewed fail information FI to store the data in the safe region. For example, according to the renewed fail information FI, the cells included in the hybrid memory device 200 corresponding to the addresses 0000000010 and 0000000011 may be the bad cells. A region included in the hybrid memory device 200 corresponding to the addresses 0000000010 and 0000000011 may be included in the fail region. The memory controller 100 may stop mapping the logical address related to the data to the physical address 0000000010 and 0000000011 of the hybrid memory device 200 based on the renewed fail information FI. The memory controller 100 may map the logical address related to the data to the physical address except for the addresses 0000000010 and 0000000011 based on the renewed fail information FI. Therefore the memory controller 100 may stop accessing the fail region included in the hybrid memory device 200.

FIG. 17 is a block diagram illustrating an example of the memory system included in a package substrate.

Referring to FIG. 17, the package substrate 15 may include the memory system 10. The memory system 10 may include the memory controller 100 and the hybrid memory device 200. The hybrid memory device 200 may include the interface 210, the non-volatile memory 230 and the volatile memory 250. The non-volatile memory 230, the volatile memory 250 and the memory controller 100 may be packaged in one chip. According to the test result of the hybrid memory device 200 performed during the operation of the memory system 10, the fail information FI may be renewed.

In an example embodiment, the fail information FI may be stored in the fail info region 233 of the non-volatile memory 230 based on a test result of the hybrid memory device 200. A test of the hybrid memory device 200 may be performed after the memory system 10 including the non-volatile memory 230, the volatile memory 250 and the memory controller 100 is packaged in one chip. If the non-volatile memory 230, the volatile memory 250 and the memory controller 100 are packaged in one chip, the test of the non-volatile memory 230 and the volatile memory 250 included in the hybrid memory may be simultaneously performed and the test efficiency of the hybrid memory device 200 may be increased.

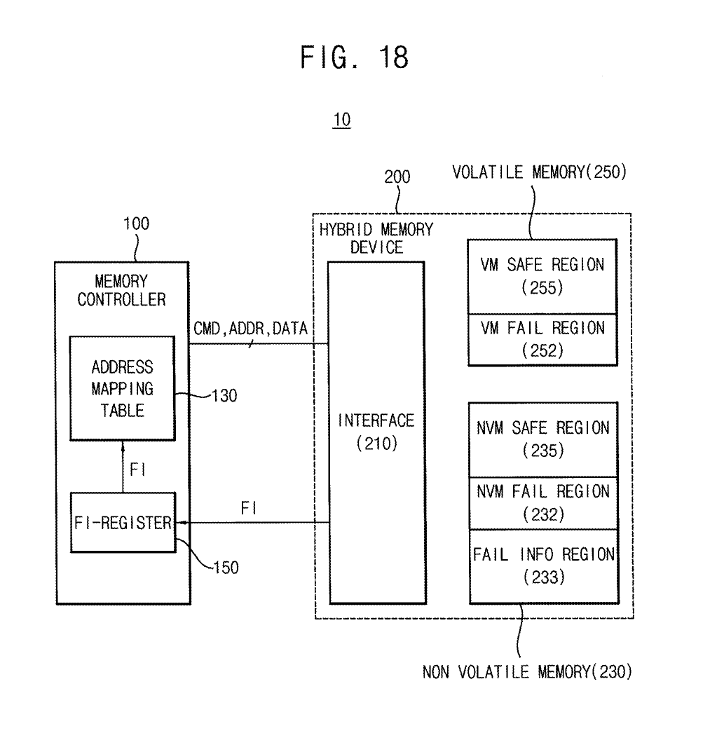

FIG. 18 is a block diagram illustrating a memory system according to example embodiments.

Referring to FIG. 18, the memory system 10 may include the memory controller 100 and the hybrid memory device 200. The memory controller 100 may include an address mapping table 130 and a fail information register 150.

The memory controller 100 may map the logical address related to the data to the physical address of the safe region based on the fail information FI and the address mapping table 130 to store the data in the safe region. The memory controller 100 reads the fail information FI from the fail info region 233 included in the hybrid memory device 200. Using commands CMD and addresses ADDR, the memory controller 100 may read the fail information FI from the fail info region 233 included in the hybrid memory device 200. The command CMD may be a read command and the addresses may be the addresses corresponding to the fail info region 233 included in the hybrid memory device 200.

As illustrated in FIGS. 12 and 18, the non-volatile memory 230 includes the data non-volatile memory data region 231 and the fail info region 233. If the unit fail information UFI corresponding to the one address included in the hybrid memory device 200 is stored in the fail information cell unit included in the fail info region 233, the space of the non-volatile memory 230 allocated to the data region included in the hybrid memory device 200 may be decreased. Therefore the address mapping table 130 may be generated by composing a mapping unit for a plurality of the addresses included in the hybrid memory device 200. If the address mapping table 130 is used, the space of the data region included in the hybrid memory device 200 may not be decreased.

The fail information FI read from the fail info region 233 may be stored in the fail information register 150 included in the memory controller 100. The memory controller 100 may store the data in the safe region included in the hybrid memory device 200 according to the address mapping table 130 and the fail information FI stored in the fail information register 150. The address mapping table 130 may be generated by grouping a plurality of the addresses included in the hybrid memory device 200.

The memory controller 100 may stop mapping the logical address related to the data to the physical address of the fail region based on the fail information FI not to store the data in the fail region included in the hybrid memory device 200. The memory controller 100 may map the logical address related to the data to the physical address of the safe region based on the fail information FI to store the data in the safe region included in the hybrid memory device 200.

In the method of operating the memory system 10 according to example of embodiments, the memory controller 100 may store the data to the safe region included in the non-volatile memory 230 and the volatile memory 250 based on the fail information FI included in the fail info region 233. According to the method of operating the memory system 10, the memory controller 100 may stop accessing the physical address corresponding to the fail region included in the non-volatile memory 230 and the volatile memory 250 based on the fail information FI and malfunction of the memory system 10 may be prevented. The fail information FI may be transmitted to system level including the memory controller 100 and, using the fail information FI, an operating system may load an application program to the safe region included in the non-volatile memory 230 and the volatile memory 250.

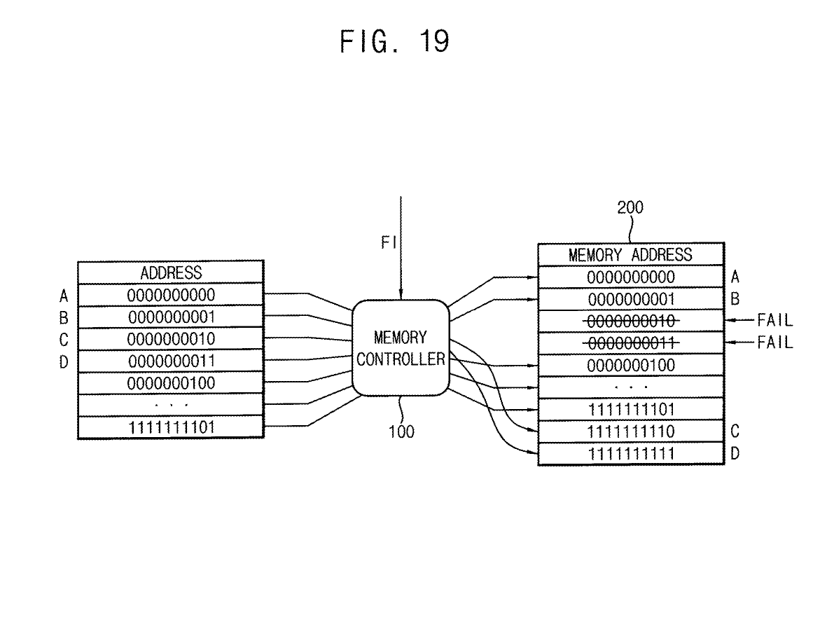

FIG. 19 is a diagram illustrating an example of mapping logical addresses to physical addresses in the memory system of FIG. 11.

Referring to FIG. 19, the memory controller 100 may map the logical address to the physical address of the safe region based on an address mapping table 130 to maintain a process order of the data.

For example, the data A, B, C and D may be assigned to each of the addresses 0000000000˜0000000011. The process order of the data may be the data A, B, C and D order. The memory controller 100 may store the data A in the physical address 0000000000 of the hybrid memory device 200. Then, the memory controller 100 may store the data B in the physical address 0000000001 of the hybrid memory device 200. Then, the memory controller 100 may store the data C in the physical address 1111111110 of the hybrid memory device 200. Then, the memory controller 100 may store the data D in the physical address 1111111111 of the hybrid memory device 200.

Also, the memory controller 100 may stop storing the data A, B, C and D in the physical address 0000000010 and 0000000011 included in the fail region of the hybrid memory device 200. The memory controller 100 may read the data from the hybrid memory device 200 in the order of the data A, B, C and D even though the data A, B, C and D are not assigned to successive physical addresses included in the hybrid memory device 200.

For example, the memory controller 100 may read the data A by accessing the physical address 0000000000 of the hybrid memory device 200. Then, the memory controller 100 may read the data B by accessing the physical address 0000000001 of the hybrid memory device 200. Then, the memory controller 100 may read the data C by accessing the physical address 1111111110 of the hybrid memory device 200. Then, the memory controller 100 may read the data D by accessing the physical address 1111111111 of the hybrid memory device 200. In this case, the memory controller 100 may map the logical address to the physical address of the safe region based on an address mapping table 130 and fail information FI to maintain a process order of the data.

In an example embodiment, the fail info region 233 in the non-volatile memory 230 may include fail information cell units 381 to 388. Each of the fail information cell units 381 to 388 may include the unit fail information UFI determined by the address mapping table 130. A mapping unit may be generated by grouping a plurality of the addresses included in the hybrid memory device 200.

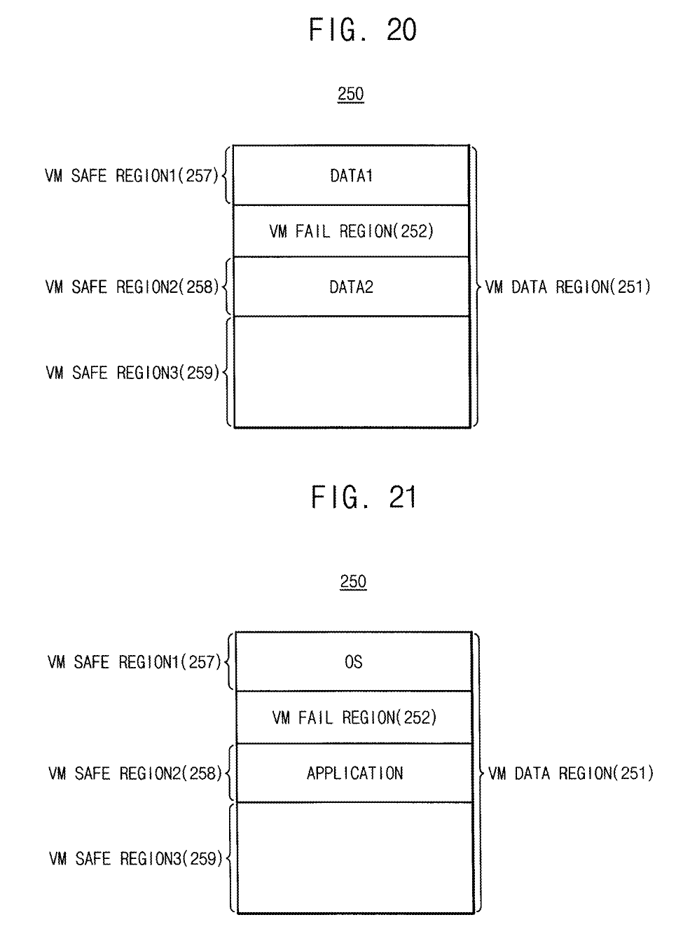

FIG. 20 is a diagram illustrating an example of data stored in a storing region of a volatile memory included in the memory system of FIG. 18.

Referring to FIG. 20, the volatile memory 250 in the memory system 10 may include a volatile memory data region 251. The volatile memory data region 251 may include a volatile memory safe region 255 and the volatile memory fail region 252.

The data transferred from the memory controller 100 may be stored in the volatile memory data region 251. The fail information FI may be information about addresses of the fail region included in the volatile memory 250 of the hybrid memory device 200.

After the memory controller 100 is initialized, the memory controller 100 may map the logical address related to the data to the physical address of the volatile memory safe region 255 based on the fail information FI to store the data in the volatile memory safe region 255 included in the hybrid memory device 200. The memory controller 100 may stop mapping the logical address related to the data to the physical address of the volatile memory fail region 252 based on the fail information FI not to store the data in the volatile memory fail region 252 included in the hybrid memory device 200.

The volatile memory data region 251 may include the volatile memory fail region 252 and the volatile memory safe region 255. The volatile memory safe region 255 may include a volatile memory safe region 1 257, a volatile memory safe region 2 258 and a volatile memory safe region 3 259. The memory controller 100 may store the data in the volatile memory safe region 255 based on the fail information FI included in the fail info region 233. For example, if the data 1 is stored in the volatile memory safe region 1 257, the data 2 may be stored in the volatile memory safe region 2 258 and the volatile memory safe region 3 259. If the data 1 is stored in the volatile memory safe region 2, the data 2 may be stored in the volatile memory safe region 1 257 and the volatile memory safe region 3 259. If the data 1 is stored in the volatile memory safe region 3 259, the data 2 may be stored in the volatile memory safe region 1 257 and the volatile memory safe region 2. If the memory controller 100 stores the data in the volatile memory fail region 252 included in the hybrid memory device 200, errors may be generated for the stored data.

FIG. 21 is a diagram illustrating an example of programs loaded in the storing region of the volatile memory included in the memory system of FIG. 18.

Referring to FIG. 21, the operating system may load the application program to the safe region based on the fail information FI. The memory controller 100 may load a program to the volatile memory safe region 255 based on the fail information FI included in the fail info region 233. For example, if the operating system is loaded to the volatile memory safe region 1 257, the application program may be loaded to the volatile memory safe region 2 258 and the volatile memory safe region 3 259. If the operating system is loaded to the volatile memory safe region 2, the application program may be loaded to the volatile memory safe region 1 257 and the volatile memory safe region 3 259. If the operating system is loaded to the volatile memory safe region 3 259, the application program may be loaded to the volatile memory safe region 1 257 and the volatile memory safe region 2. If the memory controller 100 loads the program to the volatile memory fail region 252 included in the hybrid memory device 200, errors may be generated for the loaded program.

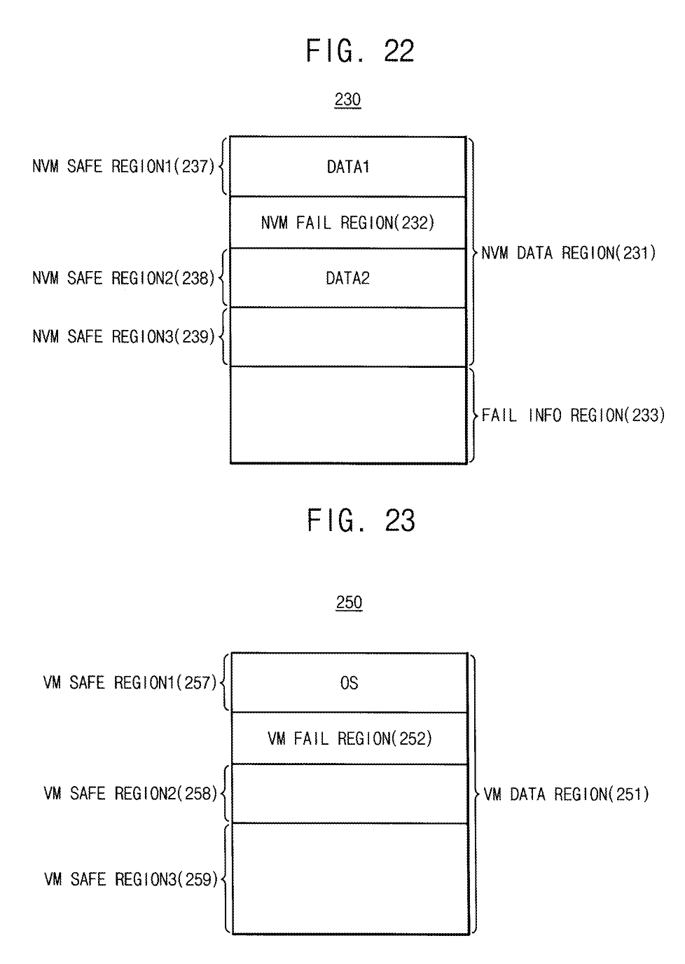

FIG. 22 is a diagram illustrating an example of the data stored in a storing region of a non-volatile memory included in the memory system of FIG. 18.

Referring to FIG. 22, the non-volatile memory 230 included in the memory system 10 may include the non-volatile memory data region 231 and the fail info region 233. The non-volatile memory data region 231 may include the non-volatile memory safe region 235 and the non-volatile memory fail region 232. The fail information FI may be stored in the fail info region 233. The fail information FI may be information about addresses of the fail region included in the non-volatile memory data region 231 of the hybrid memory device 200. The data transferred from the memory controller 100 may be stored in the non-volatile memory data region 231.

After the memory controller 100 is initialized, the memory controller 100 may map the logical address related to the data to the physical address of the non-volatile memory safe region 235 based on the fail information FI to store the data in the non-volatile memory safe region 235 included in the hybrid memory device 200. The memory controller 100 may stop mapping the logical address related to the data to the physical address of the non-volatile memory fail region 232 based on the fail information FI not to store the data in the non-volatile memory fail region 232 included in the hybrid memory device 200.

The non-volatile memory data region 231 may include the non-volatile memory fail region 232 and the non-volatile memory safe region 235. The non-volatile memory safe region 235 may include a non-volatile memory safe region 1 237, a non-volatile memory safe region 2 238 and a non-volatile memory safe region 3 239. The memory controller 100 may store the data in the non-volatile memory safe region 235 based on the fail information FI included in the fail info region 233. For example, if the data 1 is stored in the non-volatile memory safe region 1 237, the data 2 may be stored in the non-volatile memory safe region 2 238 and the non-volatile memory safe region 3 239. If the data 1 is stored in the non-volatile memory safe region 2, the data 2 may be stored in the non-volatile memory safe region 1 237 and the non-volatile memory safe region 3 239. If the data 1 is stored in the non-volatile memory safe region 3 239, the data 2 may be stored in the non-volatile memory safe region 1 237 and the non-volatile memory safe region 2. If the memory controller 100 stores the data in the non-volatile memory fail region 232 included in the hybrid memory device 200, errors may be generated for the stored.

In the method of operating the memory system 10 according to example of embodiments, the memory controller 100 may store the data to the safe region included in the non-volatile memory 230 and the volatile memory based on the fail information FI included in the fail info region 233. According to the method of operating the memory system 10, the memory controller 100 may stop accessing the physical address corresponding to the fail region included in the non-volatile memory 230 and the volatile memory 250 based on the fail information FI and malfunction of the memory system 10 may be prevented. The fail information FI may be transmitted to system level including the memory controller 100 and, using the fail information FI, an operating system may load an application program to the safe region included in the non-volatile memory 230 and the volatile memory 250.

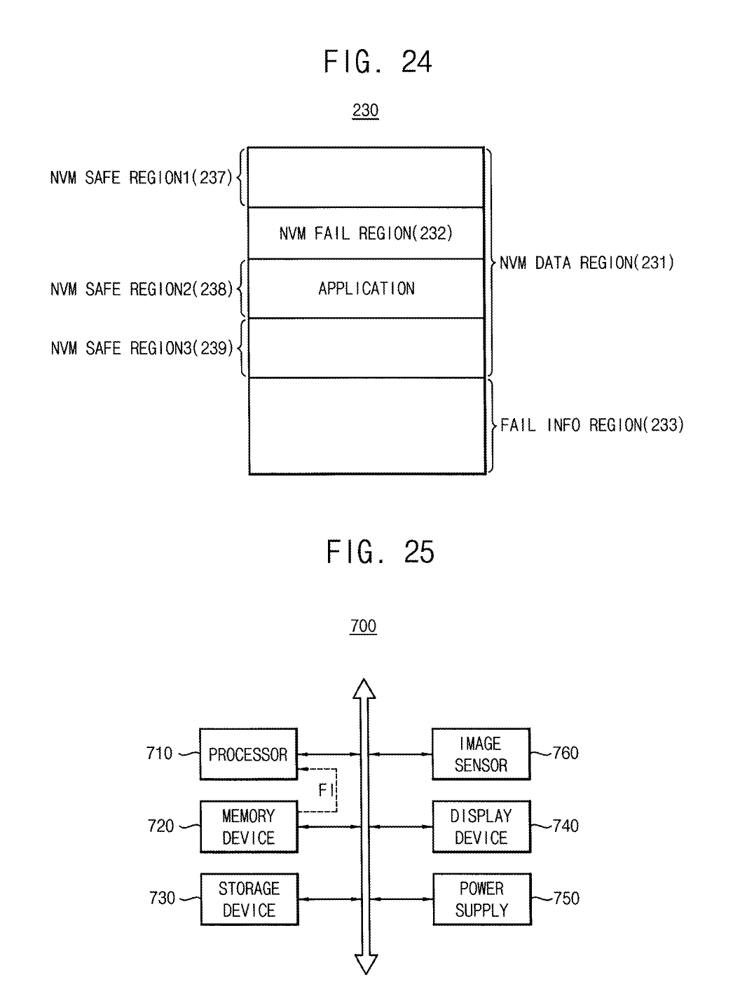

FIG. 23 is a diagram illustrating another example of the program loaded in the storing region of the volatile memory included in the memory system of FIG. 18 and FIG. 24 is a diagram illustrating an example of the program loaded in the storing region of the non volatile memory included in the memory system of FIG. 18.

Referring to FIGS. 23 and 24, the volatile memory data region 251 may include the volatile memory fail region 252 and the volatile memory safe region 255. The non-volatile memory data region 231 may include the non-volatile memory fail region 232 and the non-volatile memory safe region 235. The operating system may load the application program to the safe region based on the fail information FI. The volatile memory safe region 255 may include a volatile memory safe region 1 257, a volatile memory safe region 2 258 and a volatile memory safe region 3 259. The non-volatile memory safe region 235 may include a non-volatile memory safe region 1 237, a non-volatile memory safe region 2 238 and a non-volatile memory safe region 3 239. The memory controller 100 may load the application program to the non-volatile memory safe region 235 included in the hybrid memory device 200 based on the fail information FI.

For example, if the operating system is loaded to the volatile memory safe region 1 257, the application program may be loaded to the volatile memory safe region 2, the volatile memory safe region 3 259, the non-volatile memory safe region 1 237, the non-volatile memory safe region 2 238 and the non-volatile memory safe region 3 239. If the operating system is loaded to the volatile memory safe region 2, the application program may be loaded to the volatile memory safe region 1 257, the volatile memory safe region 3 259, the non-volatile memory safe region 1 237, the non-volatile memory safe region 2 238 and the non-volatile memory safe region 3 239. If the operating system is loaded to the volatile memory safe region 3 259, the application program may be loaded to the volatile memory safe region 1 257, the volatile memory safe region 2, the non-volatile memory safe region 1 237, the non-volatile memory safe region 2 238 and the non-volatile memory safe region 3 239. The operation system may load the application program to the safe region based on the fail information FI.

FIG. 25 is a block diagram illustrating a mobile device including the memory system according to example embodiments.

Referring to FIG. 25, a mobile device 700 may include a processor 710, a memory device 720, a storage device 730, a display device 740, a power supply 750 and an image sensor 760. The mobile device 700 may further include ports that communicate with a video card, a sound card, a memory card, a USB device, other electronic devices, etc.

The processor 710 may perform various calculations or tasks. According to embodiments, the processor 710 may be a microprocessor or a CPU. The processor 710 may communicate with the memory device 720, the storage device 730, and the display device 740 via an address bus, a control bus, and/or a data bus. In some embodiments, the processor 710 may be coupled to an extended bus, such as a peripheral component interconnection (PCI) bus. The memory device 720 may store data for operating the mobile device 700. For example, the memory device 720 may be implemented with a dynamic random access memory (DRAM) device, a mobile DRAM device, a static random access memory (SRAM) device, a phase-change random access memory (PRAM) device, a ferroelectric random access memory (FRAM) device, a resistive random access memory (RRAM) device, and/or a magnetic random access memory (MRAM) device. The memory device 720 may include the data loading circuit according to example embodiments. For example, the memory device 720 may include the memory system 10.

The storage device 730 may include a solid state drive (SSD), a hard disk drive (HDD), a CD-ROM, etc. The mobile device 700 may further include an input device such as a touchscreen, a keyboard, a keypad, a mouse, etc., and an output device such as a printer, a display device, etc. The power supply 750 supplies operation voltages for the mobile device 700.

The image sensor 760 may communicate with the processor 710 via the buses or other communication links. The image sensor 760 may be integrated with the processor 710 in one chip, or the image sensor 760 and the processor 710 may be implemented as separate chips.

At least a portion of the mobile device 700 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP). The mobile device 700 may be a digital camera, a mobile phone, a smart phone, a portable multimedia player (PMP), a personal digital assistant (PDA), a computer, etc.

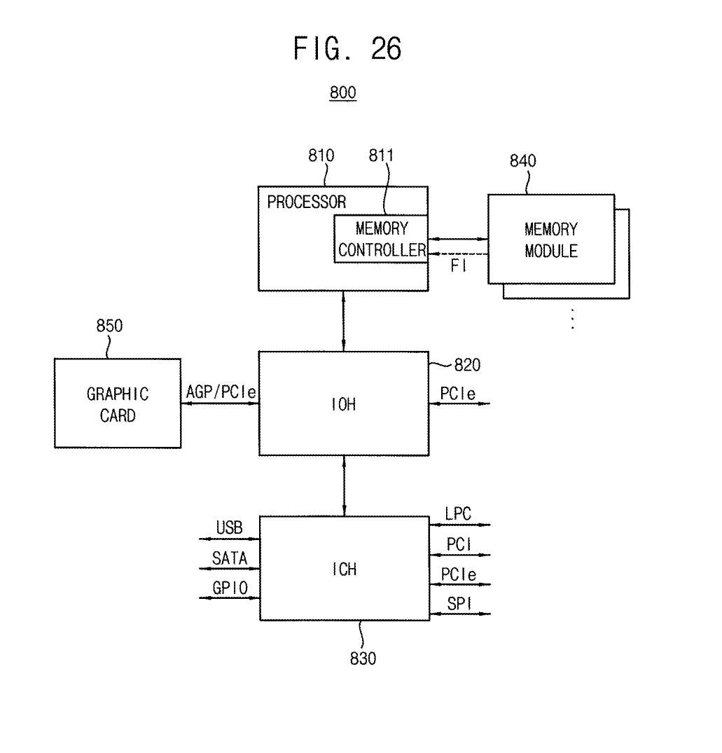

FIG. 26 is a block diagram illustrating a computing system including the memory system according to example embodiments.

Referring to FIG. 26, a computing system 800 includes a processor 810, an input/output hub (IOH) 820, an input/output controller hub (ICH) 830, at least one memory module 840 and a graphics card 850. In some embodiments, the computing system 800 may be a personal computer (PC), a server computer, a workstation, a laptop computer, a mobile phone, a smart phone, a personal digital assistant (PDA), a portable multimedia player (PMP), a digital camera), a digital television, a set-top box, a music player, a portable game console, a navigation system, etc.

The processor 810 may perform various computing functions, such as executing specific software for performing specific calculations or tasks. For example, the processor 810 may be a microprocessor, a central process unit (CPU), a digital signal processor, or the like. In some embodiments, the processor 810 may include a single core or multiple cores. For example, the processor 810 may be a multi-core processor, such as a dual-core processor, a quad-core processor, a hexa-core processor, etc. In some embodiments, the computing system 800 may include a plurality of processors. The processor 810 may include an internal or external cache memory.

The processor 810 may include a memory controller 811 for controlling operations of the memory module 840. The memory controller 811 and the memory module 840 may be the memory controller 100 and the memory device 200a, respectively. The memory controller 811 included in the processor 810 may be referred to as an integrated memory controller (IMC). A memory interface between the memory controller 811 and the memory module 840 may be implemented with a single channel including a plurality of signal lines, or may be implemented with multiple channels, to each of which at least one memory module 840 may be coupled. In some embodiments, the memory controller 811 may be located inside the input/output hub 820, which may be referred to as memory controller hub (MCH).

The input/output hub 820 may manage data transfer between processor 810 and devices, such as the graphics card 850. The input/output hub 820 may be coupled to the processor 810 via various interfaces. For example, the interface between the processor 810 and the input/output hub 820 may be a front side bus (FSB), a system bus, a HyperTransport, a lightning data transport (LDT), a QuickPath interconnect (QPI), a common system interface (CSI), etc. In some embodiments, the computing system 800 may include a plurality of input/output hubs. The input/output hub 820 may provide various interfaces with the devices. For example, the input/output hub 820 may provide an accelerated graphics port (AGP) interface, a peripheral component interface-express (PCIe), a communications streaming architecture (CSA) interface, etc.

The graphics card 850 may be coupled to the input/output hub 820 via AGP or PCIe. The graphics card 850 may control a display device (not shown) for displaying an image. The graphics card 850 may include an internal processor for processing image data and an internal memory device. In some embodiments, the input/output hub 820 may include an internal graphics device along with or instead of the graphics card 850 outside the graphics card 850. The graphics device included in the input/output hub 820 may be referred to as integrated graphics. Further, the input/output hub 820 including the internal memory controller and the internal graphics device may be referred to as a graphics and memory controller hub (GMCH).

The input/output controller hub 830 may perform data buffering and interface arbitration to efficiently operate various system interfaces. The input/output controller hub 830 may be coupled to the input/output hub 820 via an internal bus, such as a direct media interface (DMI), a hub interface, an enterprise Southbridge interface (ESI), PCIe, etc. The input/output controller hub 830 may provide various interfaces with peripheral devices. For example, the input/output controller hub 830 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In some embodiments, the processor 810, the input/output hub 820 and the input/output controller hub 830 may be implemented as separate chipsets or separate integrated circuits. In other embodiments, at least two of the processor 810, the input/output hub 820 and the input/output controller hub 830 may be implemented as a single chipset.

Example embodiments of the inventive concepts may be applied to systems such as be a mobile phone, a smart phone, a personal digital assistant (PDA), a portable multimedia player (PMP), a digital camera, a music player, a portable game console, a navigation system, etc. The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the inventive concepts. Accordingly, all such modifications are intended to be included within the scope of the inventive concepts as defined in the claims.

In the method of operating the memory system according to example embodiments, the memory controller may store the data to the safe region included in the non-volatile memory and the volatile memory based on the fail information FI included in the fail info region. According to the method of operating the memory system, the memory controller may stop accessing the physical address corresponding to the fail region included in the non-volatile memory and the volatile memory based on the fail information FI and malfunction of the memory system may be prevented. The fail information FI may be transmitted to system level including the memory controller.

What is claimed is:

1. A method of operating memory system including a memory device and a memory controller, the method comprising:
reading, by the memory controller, fail information from a fail info region included in the memory device;
mapping, by the memory controller, a logical address related to a program to a physical address of a safe region based on the fail information, the safe region being a region of the memory device distinct from the fail info region and a fail region included in the memory device; and
loading, by the memory controller, the program into the safe region according to the mapping.

2. The method of claim 1, wherein the memory device further includes a data region,
the memory controller is configured to store data in the data region, and
the fail info region is within a non-volatile memory of the memory device and the data region is within a volatile memory of the memory device.

3. The method of claim 1, further comprising:
testing the memory device before the memory device is packaged; and
storing the fail information in the fail info region based on a result of the testing.

4. The method of claim 3, wherein the fail info region includes fail information cell units, each of the fail information cell units storing a unit fail information, and
the memory controller is configured to determine that a portion of the memory device is bad if corresponding unit fail information is at a first level, and
the memory controller is configured to determine that a portion of the memory device is good if corresponding unit fail information is at a second level different from the first level.

5. The method of claim 4, wherein each of the fail information cell units includes an electrical fuse, and the method further comprises:
storing the unit fail information in the fail information cell units by programming the electrical fuse.

6. The method of claim 1, wherein the mapping is determined according to the fail information stored in fail information cell units of the fail info region.

7. The method of claim 1, wherein the program is a boot loader or an operating system.

8. The method of claim 7, wherein the operating system is configured to load an application program into the safe region based on the fail information.

9. The method of claim 1, wherein the mapping of the logical address related to the program to the physical address of the safe region is further based on an address mapping table, the address mapping table indicating an order to process data.

10. A method of operating memory system including a hybrid memory device and a memory controller, the hybrid memory device including a non-volatile memory and a volatile memory, the method comprising:
reading, by the memory controller, fail information of the non-volatile memory and the volatile memory from a fail info region of the hybrid memory device;
mapping, by the memory controller, a logical address related to data to a physical address of a safe region based on the fail information, the safe region being a region of the memory device distinct from the fail info region and a fail region of the hybrid memory device; and
storing, by the memory controller, the data in the safe region according to the mapping.

11. The method of claim 10, wherein the fail info region is a region of the non-volatile memory, the non-volatile memory including a non-volatile memory fail region and a non-volatile memory safe region,
the volatile memory includes a volatile memory fail region and a volatile memory safe region, and
the memory controller is configured to store data in one or more of the non-volatile memory safe region and the volatile memory safe region.

12. The method of claim 11, further comprising:
testing the hybrid memory device while the memory system is operated; and
renewing the fail information stored in the fail info region based on a result of the testing.

13. The method of claim 12, wherein the memory controller is configured to re-map the logical address to the physical address of the safe region based on the renewed fail information.

14. The method of claim 10, further comprising:
testing the hybrid memory device after the memory system including the non-volatile memory, the volatile memory and the memory controller is packaged in a same chip,
storing the fail information in the fail info region of the non-volatile memory based on the testing.

15. A method of operating a memory device, the method comprising:
reading, by a memory controller, fail information from a non-volatile memory of the memory device, the fail information indicating bad sectors of the memory device;
mapping, by the memory controller, logical addresses of a program to physical addresses of the memory device based on the fail information such that the mapping prevents the program from accessing the bad sectors; and
loading, by the memory controller, the program into the mapped physical addresses.

16. The method of claim 15, further comprising:
testing the memory device for the bad sectors at a time of manufacturing a same; and
programming the non-volatile memory with the fail information based on the testing.

17. The method of claim 16, wherein the fail information is stored in corresponding fail information cells included in the non-volatile memory,
each of the fail information cells includes an electrical fuse, and
the programming the non-volatile memory includes breaking the fuse based on the testing.

18. The method of claim 16, further comprising:
retesting the memory device for the bad sectors at a time of operating the same; and
updating the fail information programmed in the non-volatile memory based on the retesting.

19. The method of claim 15, wherein the reading the fail information from the memory device includes transferring the fail information from the non-volatile memory to an address mapping table in the memory controller, the address mapping table indicating an order to process data.

20. The method of claim 15, wherein the loading the program loads the program such that the program is not loaded into fail regions of the memory device, the fail regions being regions of the memory device containing the bad sectors.
